(19) United States
(12) Patent Application Publication
(10) Pub. No.: US 2024/0113164 A1
(43) Pub. Date: Apr. 4, 2024

(54) FILM MODIFICATION FOR GATE CUT PROCESS

(71) Applicant: Taiwan Semiconductor Manufacturing Co., Ltd., Hsinchu (TW)

(72) Inventors: Heng-Chia Su, Hsinchu (TW); Li-Fong Lin, Hsinchu (TW); Zhen-Cheng Wu, Hsinchu (TW); Chi On Chui, Hsinchu (TW)

(21) Appl. No.: 18/151,792

(22) Filed: Jan. 9, 2023

Related U.S. Application Data
(60) Provisional application No. 63/411,992, filed on Sep. 30, 2022.

(51) Int. Cl. H01L 29/06; H01L 21/762; H01L 21/768; H01L 21/8234; H01L 29/66; H01L 29/78; H01L 29/786

(52) U.S. Cl. CPC H01L 29/0673; H01L 21/76224; H01L 21/76843; H01L 21/823412; H01L 21/823481; H01L 29/66545; H01L 29/66795; H01L 29/7851; H01L 29/78696

(57) ABSTRACT

A process for converting a portion of a dielectric fill material into a hard mask includes a nitrogen treatment or nitrogen plasma to convert a portion of the dielectric fill material into a nitrogen-like layer for serving as a hard mask to form an edge area of a device die by an etching process. After forming the edge area, another dielectric fill material is provided in the edge area. In the completed device, a gate cut area can have a gradient of nitrogen concentration at an upper portion of the gate cut dielectric of the gate cut area.

### PRIORITY CLAIM AND CROSS-REFERENCE

This application claims the benefit of U.S. Provisional Application No. 63/411,992, filed on Sep. 30, 2022, which application is hereby incorporated herein by reference

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5, 6A, 6B, 7A, 7B, 8A, 8B, 9A, 9B, 10A, 10B, 11A, 11B, 11C, 12A, 12B, 12C, 12D, 13A, 13B, 13C, 14A, 14B, 15A, 15B, 16A, 16B, 17A, 17B, 17C, 17D, 17E, 18A, 18B, 18C, 19, 20, 21, 22A, 22B, 22C, 22D, 22E, 22F, 23A, 23B, 23C, 23D, 23E, 23F, 24A, 24B, 24C, 24D, 24E, 25A, 25B, 25C, 26A, 26B, 26C, and 27A are cross-sectional views of intermediate stages in the manufacturing of nano-FETs, in accordance with some embodiments.

FIGS. 27B and 27C illustrate dopant concentration profiles along a thickness direction of the gate cut dielectric gate, in accordance with some embodiments.

FIGS. 28A, 28B, 28C, and 28D are cross-sectional views of a nano-FET, in accordance with some embodiments.

FIG. 29 illustrates an example of a fin field-effect transistor (FinFET) in a three-dimensional view, in accordance with some embodiments.

FIGS. 30A and 30B illustrate an example of a FinFET, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

As discussed in greater detail below, embodiments illustrated in the present disclosure provide semiconductor devices having an edge isolation region. The edge isolation region may be used to provide isolation between adjacent devices which are formed on a single wafer. When a semiconductor wafer is patterned, the patterning may be done uniformly to help avoid patterning defects. The pattern may be later adjusted by a process of gate or fin cutting to form desired device configurations. In some embodiments, several gate structures and/or fin structures are removed at edges of devices to provide isolation between devices. Rather than form a separate mask for the edge etch, embodiments provide a treatment process which converts a portion of a dielectric refill layer—such as used after cutting a metal gate—into a hard mask to protect areas of the device from etching during etching the edge portions. The conversion of the dielectric fill material into a hard mask saves the steps of having to remove portions of the dielectric fill material, and forming a series of masks over the device to protect the kept device areas.

Embodiments are described below in a particular context, e.g., a die comprising nano-FETs. Various embodiments may be applied, however, to dies comprising other types of transistors (e.g., fin field effect transistors (FinFETs), planar transistors, or the like) in lieu of or in combination with the nano-FETs. Some examples of some of such embodiments are described below as well.

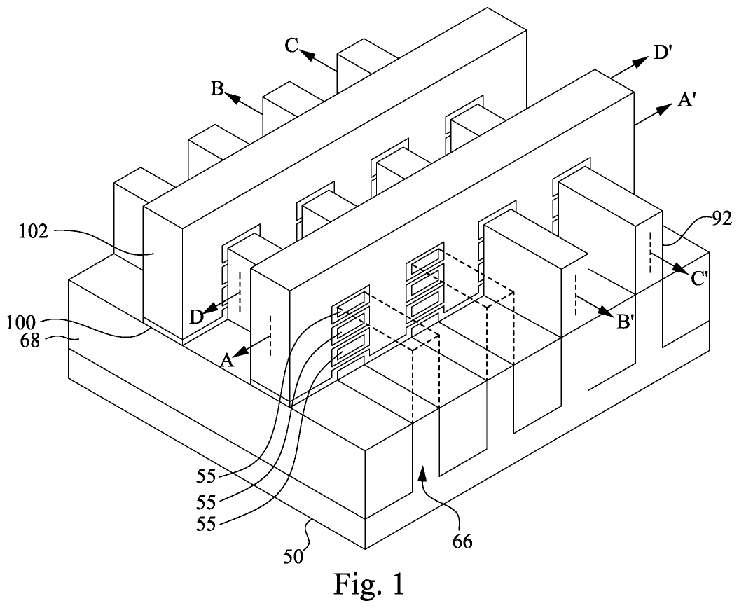

FIG. 1 illustrates an example of nano-FETs (e.g., nanowire FETs, nanosheet FETs, or the like) in a three-dimensional view, in accordance with some embodiments. The nano-FETs comprise nanostructures 55 (e.g., nanosheets, nanowire, or the like) over fins 66 on a substrate 50 (e.g., a semiconductor substrate), wherein the nanostructures 55 act as channel regions for the nano-FETs. The nanostructure 55 may include p-type nanostructures, n-type nanostructures, or a combination thereof. Isolation regions 68 are disposed between adjacent fins 66, which may protrude above and from between neighboring isolation regions 68. Although the isolation regions 68 are described/illustrated as being separate from the substrate 50, as used herein, the term “substrate” may refer to the semiconductor substrate alone or a combination of the semiconductor substrate and the isolation regions. Additionally, although a bottom portion of the fins 66 is illustrated as being single, continuous materials with the substrate 50, the bottom portion of the fins 66 and/or the substrate 50 may comprise a single material or a plurality of materials. In this context, the fins 66 refer to the portion extending between the neighboring isolation regions 68.

Gate dielectric layers 100 are over top surfaces of the fins 66 and along top surfaces, sidewalls, and bottom surfaces of the nanostructures 55. Gate electrodes 102 are over the gate dielectric layers 100. Epitaxial source/drain regions 92 are disposed on the fins 66 on opposing sides of the gate dielectric layers 100 and the gate electrodes 102. Source/drain region(s) 92 may refer to a source or a drain, individually or collectively dependent upon the context.

FIG. 1 further illustrates reference cross-sections that are used in later figures. Cross-section A-A′ is along a longitudinal axis of a gate electrode 102 and in a direction, for example, perpendicular to the direction of current flow between the epitaxial source/drain regions 92 of a nano-FET. Cross-section B-B′ is perpendicular to cross-section A-A′ and is parallel to a longitudinal axis of a fin 66 of the nano-FET in a first threshold region and in a direction of, for example, a current flow between the epitaxial source/drain regions 92 of the nano-FET in the first threshold region. Cross-section C-C′ is parallel to cross-section B-B′ and is parallel to a longitudinal axis of a fin 66 of the nano-FET in a second threshold region and in a direction of, for example, a current flow between the epitaxial source/drain regions 92 of the nano-FET in the second threshold region. Subsequent figures refer to these reference cross-sections for clarity. Cross-section D-D′ is parallel to cross-section A-A′ and extends through epitaxial source/drain regions of the nano-FETs. Subsequent figures refer to these reference cross-sections for clarity.

Some embodiments discussed herein are discussed in the context of nano-FETs formed using a gate-last process. In other embodiments, a gate-first process may be used. Also, some embodiments contemplate aspects used in planar devices, such as planar FETs or in fin field-effect transistors (FinFETs).

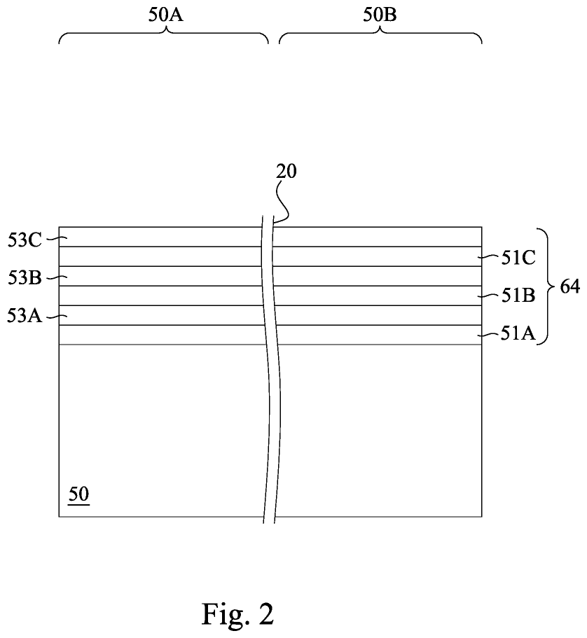

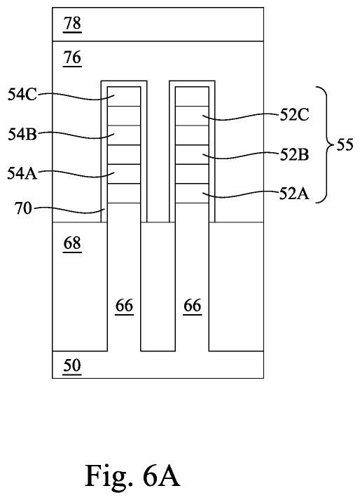

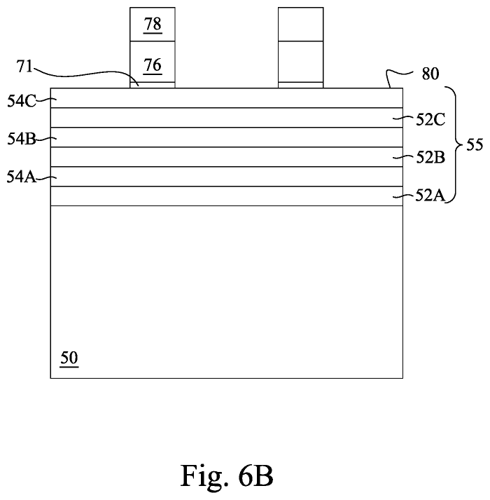

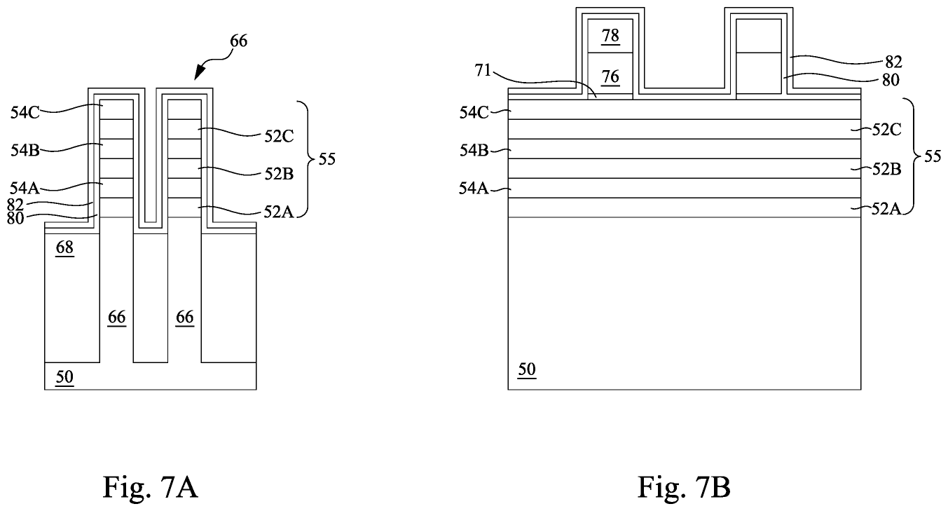

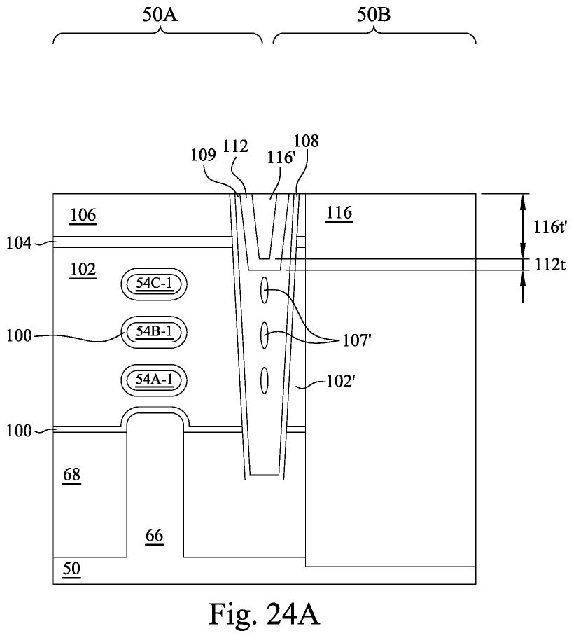

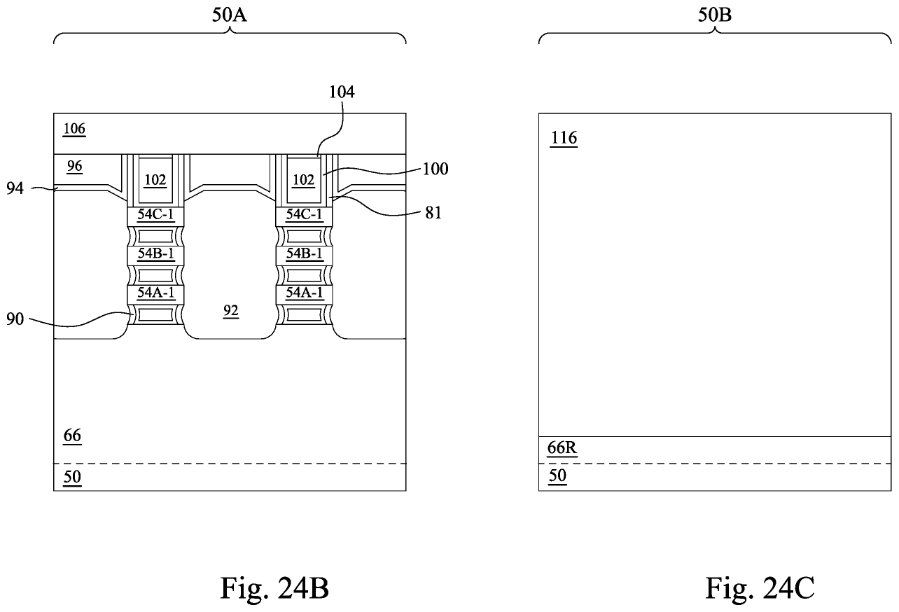

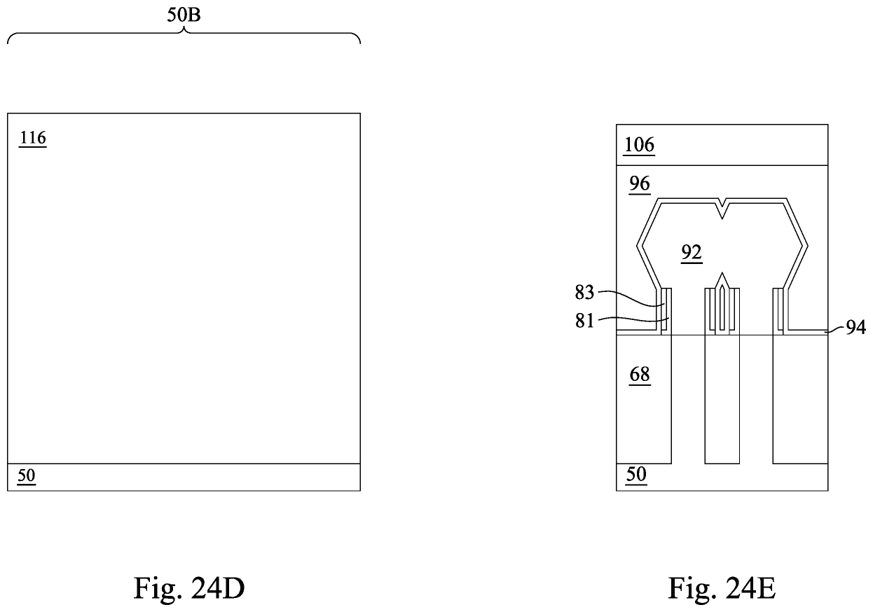

FIGS. 2 through 36C are cross-sectional views of intermediate stages in the manufacturing of nano-FETs, in accordance with some embodiments. FIGS. 2 through 5, 6A, 13A, 14A, 15A, 16A, 17A, 18A, 19, 20, 21, 22A, 22B, 22C, 22D, 22E, 22F, 23A, 23B, 23C, 23D, 23E, 23F, 24A, 25A, 26A, and 27A illustrate reference cross-section A-A′ illustrated in FIG. 1. FIGS. 6B, 7B, 8B, 9B, 10B, 11B, 11C, 12B, 12D, 13B, 14B, 15B, 16B, 17B, 18B, 24B, 25B, and 26B illustrate reference cross-section B-B′ illustrated in FIG. 1. FIGS. 24C and 24D illustrate reference cross-section C-C′ illustrated in FIG. 1. FIGS. 7A, 8A, 9A, 10A, 11A, 12A, 12C, 13C, 17C, 18C, 24E, 25C, and 26C illustrate reference cross-section D-D′ illustrated in FIG. 1.

In FIG. 2, a substrate 50 is provided for forming the nano-FETs. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

The substrate 50 includes a first region 50A and a second region 50B. In some embodiments, the first region 50A and the second region 50B are for forming different devices. For example, the first region 50A may be a logic device region, and the second region 50B may be an I/O device region. Alternatively, both the first region 50A and the second region 50B are the logic device region or the I/O region with different functional circuits. In some embodiments, the first region 50A and the second region 50B may be used for forming devices of the same conductivity type or different conductivity types. For example, in an embodiment, both the first region 50A and the second region 50B are for forming n-type devices, such as NMOS transistors (e.g., n-type nano-FETs), or p-type devices, such as PMOS transistors (e.g., p-type nano-FETs). In some embodiments, the first region 50A can be for forming n-type devices, such as an NMOS device region for forming NMOS transistors (e.g., n-type nano-FETs), and the second region 50B can be for forming p-type devices, such as a PMOS device region for forming PMOS transistors (e.g., p-type nano-FETs). The first region 50A may be physically separated from the second region 50B (as illustrated by divider 20), and any number of device features (e.g., other active devices, doped regions, isolation structures, etc.) may be disposed between the first region 50A and the second region 50B. Although one first region 50A and one second region 50B are illustrated, any number of first regions 50A and second regions 50B may be provided. For the sake of simplicity, only one region is illustrated in the subsequent Figures, however, it should be understood that the processes described below may be utilized in any of the regions contemplated. Descriptions are provided below for handling multiple regions, including for example, masking one or more regions while performing processes on the other region(s). Where different processes or materials may be used for different regions, such will be noted within the context of the discussion.

Further in FIG. 2, a multi-layer stack 64 is formed over the substrate 50. The multi-layer stack 64 includes alternating layers of first semiconductor layers 51A-51C (collectively referred to as first semiconductor layers 51) and second semiconductor layers 53A-53C (collectively referred to as second semiconductor layers 53). The first semiconductor materials and the second semiconductor materials may be materials having a high-etch selectivity to one another. As such, the first semiconductor layers 51 of the first semiconductor material may be removed without significantly removing the second semiconductor layers 53 of the second semiconductor material. Similarly, the second semiconductor layers 53 of the second semiconductor material may be removed without significantly removing the first semiconductor layers 51. For purposes of illustration and as discussed in greater detail below, the first semiconductor layers 51 will be removed, and the second semiconductor layers 53 will be patterned to form channel regions of the nano-FETs in both the first region 50A and the second region 50B. Nevertheless, in some embodiments, the second semiconductor layer 53 will be removed, and the first semiconductor layer 51 may be patterned to form channel regions of the nano-FETs. In such embodiments, the channel regions in both the first region 50A and the second region 50B may have a same material composition (e.g., silicon or other suitable semiconductor materials) and be formed simultaneously.

In still other embodiments, the first semiconductor layers 51 will be removed in the first region 50A, and the second semiconductor layers 53 will be patterned to form channel regions of the nano-FETs in the first region 50A. Also, the second semiconductor layer 53 will be removed, and the first semiconductor layer 51 will be patterned to form channel regions of the nano-FETs in the second region 50B. Nevertheless, in some embodiments, the second semiconductor layers 53 may be removed, and the first semiconductor layers 51 may be patterned to form channel regions of the nano-FETs in the first region 50A, and the first semiconductor layers 51 may be removed, and the second semiconductor layers 53 may be patterned to form channel regions of the nano-FETs in the second region 50B. In such embodiments, the channel regions in both the first region 50A and the second region 50B have different material compositions (e.g., one is silicon, silicon carbide, or the like, and another is silicon germanium or another semiconductor material). FIGS. 36A, 36B, and 36C illustrate a structure resulting from such embodiments where the channel region in the first region 50A formed of a semiconductor material such as silicon or silicon carbide, and the channel region in the second region 50B formed of another semiconductor material such as silicon germanium, for example.

The multi-layer stack 64 is illustrated as including three layers of each of the first semiconductor layers 51 and the second semiconductor layers 53 for illustrative purposes. In some embodiments, the multi-layer stack 64 may include any number of the first semiconductor layers 51 and the second semiconductor layers 53. Each of the layers of the multi-layer stack 64 may be epitaxially grown using a process such as chemical vapor deposition (CVD), atomic layer deposition (ALD), vapor phase epitaxy (VPE), molecular beam epitaxy (MBE), or the like.

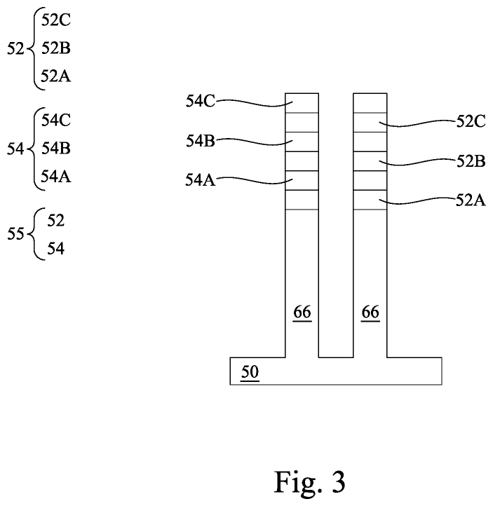

Referring to FIG. 3, fins 66 are formed in the substrate 50, and nanostructures 55 are formed in the multi-layer stack 64, in accordance with some embodiments. In some embodiments, the nanostructures 55 and the fins 66 may be formed in the multi-layer stack 64 and the substrate 50, respectively, by etching trenches in the multi-layer stack 64 and the substrate 50. The etching may be any acceptable etch process, such as a reactive ion etch (RIE), neutral beam etch (NBE), the like, or a combination thereof. The etching may be anisotropic. Forming the nanostructures 55 by etching the multi-layer stack 64 may further define first nanostructures 52A-52C (collectively referred to as the first nanostructures 52) from the first semiconductor layers 51 and define second nanostructures 54A-54C (collectively referred to as the second nanostructures 54) from the second semiconductor layers 53. The first nanostructures 52 and the second nanostructures 54 may further be collectively referred to as nanostructures 55.

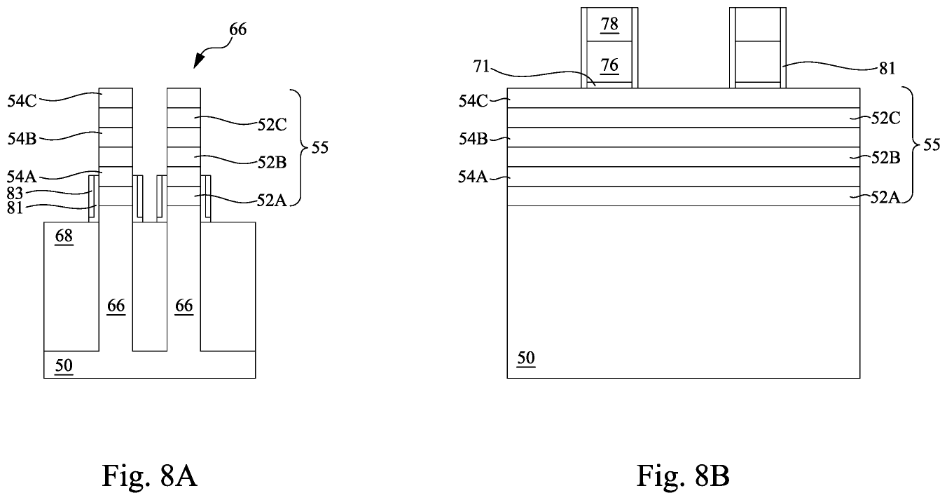

The fins 66 and the nanostructures 55 may be patterned by any suitable method. For example, the fins 66 and the nanostructures 55 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 66. Such a process is illustrated with respect to FIGS. 8A-8B, and discussed in further detail below.

FIG. 3 illustrates the fins 66 as having substantially equal widths for illustrative purposes. In some embodiments, widths of the fins 66 in the first region 50A may be greater or thinner than the fins 66 in the second region 50B. Further, while each of the fins 66 and the nanostructures 55 are illustrated as having a consistent width throughout, in some embodiments, the fins 66 and/or the nanostructures 55 may have tapered sidewalls such that a width of each of the fins 66 and/or the nanostructures 55 continuously increases in a direction towards the substrate 50. In such embodiments, each of the nanostructures 55 may have a different width and be trapezoidal in shape.

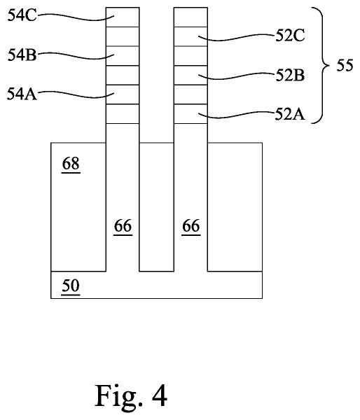

In FIG. 4, shallow trench isolation (STI) regions 68 are formed adjacent the fins 66. The STI regions 68 may be formed by depositing an insulation material over the substrate 50, the fins 66, and nanostructures 55, and between adjacent fins 66. The insulation material may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In the illustrated embodiment, the insulation material is silicon oxide formed by an FCVD process. An anneal process may be performed once the insulation material is formed. In an embodiment, the insulation material is formed such that excess insulation material covers the nanostructures 55. Although the insulation material is illustrated as a single layer, some embodiments may utilize multiple layers. For example, a liner (not separately illustrated) may first be formed along a surface of the substrate 50, the fins 66, and the nanostructures 55. Thereafter, a fill material, such as those discussed above may be formed over the liner.

A removal process is then applied to the insulation material to remove excess insulation material over the nanostructures 55. In some embodiments, a planarization process such as a chemical mechanical polish (CMP), an etch-back process, combinations thereof, or the like may be utilized. The planarization process exposes the nanostructures 55 such that top surfaces of the nanostructures 55 and the insulation material are level after the planarization process is complete.

The insulation material is then recessed to form the STI regions 68. The insulation material is recessed such that upper portions of fins 66 protrude from between neighboring STI regions 68. Further, the top surfaces of the STI regions 68 may have a flat surface as illustrated, a convex surface, a concave surface (such as dishing), or a combination thereof. The top surfaces of the STI regions 68 may be formed flat, convex, and/or concave by an appropriate etch. The STI regions 68 may be recessed using an acceptable etching process, such as one that is selective to the material of the insulation material (e.g., etches the material of the insulation material at a faster rate than the material of the fins 66 and the nanostructures 55). For example, an oxide removal using, for example, dilute hydrofluoric (dHF) acid may be used.

The process described above with respect to FIGS. 2 through 4 is just one example of how the fins 66 and the nanostructures 55 may be formed. In some embodiments, the fins 66 and/or the nanostructures 55 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 66 and/or the nanostructures 55. The epitaxial structures may comprise the alternating semiconductor materials discussed above, such as the first semiconductor materials and the second semiconductor materials. In some embodiments where epitaxial structures are epitaxially grown, the epitaxially grown materials may be in situ doped during growth, which may obviate prior and/or subsequent implantations, although in situ and implantation doping may be used together.

Further in FIG. 4, appropriate wells (not separately illustrated) may be formed in the fins 66 and nanostructures 55, and/or the substrate 50. The wells may have a conductivity type opposite from a conductivity type of source/drain regions that will be subsequently formed in each of the regions 50A and 50B, etc. For example, in some embodiments, a p-type well is formed in an n-type region, and an n-type well is formed in a p-type region. In some embodiments, a p-type well or an n-type well is formed in both the n-type region and the p-type region. The n-type well may be formed by performing an n-type impurity implant. The n-type impurities may be phosphorus, arsenic, antimony, or the like implanted in the region to a concentration in the range of 10¹³ cm⁻³ to 10¹⁴ cm⁻³. The p-type well may be formed by performing a p-type impurity implant. The p-type impurities may be boron, boron fluoride, indium, or the like implanted in the region to a concentration in the range of 10¹³ cm⁻³ to 10¹⁴ cm⁻³. After the implants are implanted, an anneal process may be performed to repair damage and activate the p-type and/or n-type impurities that were implanted. In some embodiments where epitaxial structures are epitaxially grown for the fins 66 and the nanostructures 55, the grown materials may be in situ doped during growth, which may obviate the implantations, although in situ and implantation doping may be used together.

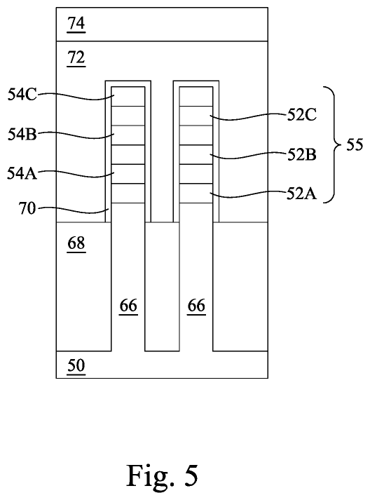

In FIG. 5, a dummy dielectric layer 70 is formed on the fins 66 and/or the nanostructures 55. The dummy dielectric layer 70 may be, for example, silicon oxide, silicon nitride, a combination thereof, or the like, and may be deposited or thermally grown according to acceptable techniques. A dummy gate layer 72 is formed over the dummy dielectric layer 70, and a mask layer 74 is formed over the dummy gate layer 72. The dummy gate layer 72 may be deposited over the dummy dielectric layer 70 and then planarized, such as by a chemical mechanical polishing (CMP). The mask layer 74 may be deposited over the dummy gate layer 72. The dummy gate layer 72 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 72 may be deposited by physical vapor deposition (PVD), CVD, sputter deposition, or other techniques for depositing the selected material. The dummy gate layer 72 may be made of other materials that have a high etching selectivity from the etching of isolation regions. The mask layer 74 may include, for example, silicon nitride, silicon oxynitride, or the like. In some embodiments, the mask layer 74 may include both an oxide layer and a nitride layer, such as silicon oxide and silicon nitride. In some embodiments, the same dummy gate layer 72 and mask layer 74 are formed across both the first region 50A and the second region 50B. It is noted that the dummy dielectric layer 70 is shown covering only the fins 66 and the nanostructures 55 for illustrative purposes only. In some embodiments, the dummy dielectric layer 70 may be deposited such that the dummy dielectric layer 70 covers the STI regions 68, such that the dummy dielectric layer 70 extends between the dummy gate layer 72 and the STI regions 68.

FIGS. 6A through 26C illustrate various additional steps in the manufacturing of embodiment devices. FIGS. 1 through 16A and 16B, 17B, 17C, 17D, 17E, 18B, 18C, 24E, 25C, and 26C illustrate features in either the first region 50A or the second region 50B.

In FIGS. 6A and 6B, the mask layer 74 (see FIG. 5) may be patterned using acceptable photolithography and etching techniques to form masks 78. The pattern of the masks 78 then may be transferred to the dummy gate layer 72 and to the dummy dielectric layer 70 to form dummy gates 76 and dummy gate dielectrics 71, respectively. The dummy gates 76 cover respective channel regions of the fins 66. The pattern of the masks 78 may be used to physically separate each of the dummy gates 76 from adjacent dummy gates 76. The dummy gates 76 may also have a lengthwise direction substantially perpendicular to the lengthwise direction of respective fins 66.

In FIGS. 7A and 7B, a first spacer layer 80 and a second spacer layer 82 are formed over the structures illustrated in FIGS. 6A and 6B, respectively. The first spacer layer 80 and the second spacer layer 82 will be subsequently patterned to act as spacers for forming self-aligned source/drain regions. In FIGS. 7A and 7B, the first spacer layer 80 is formed on top surfaces of the STI regions 68; top surfaces and sidewalls of the fins 66, the nanostructures 55 and the masks 78; sidewalls of the dummy gates 76 and the dummy gate dielectrics 71. The second spacer layer 82 is deposited over the first spacer layer 80. The first spacer layer 80 may be formed of silicon oxide, silicon nitride, silicon oxynitride, or the like, using techniques such as thermal oxidation or deposited by CVD, ALD, or the like. The second spacer layer 82 may be formed of a material having a different etch rate than the material of the first spacer layer 80, such as silicon oxide, silicon nitride, silicon oxynitride, or the like, and may be deposited by CVD, ALD, or the like.

After forming the first spacer layer 80 and prior to forming the second spacer layer 82, implants for lightly doped source/drain (LDD) regions (not separately illustrated) may be performed. Appropriate type impurities (e.g., n-type or p-type) may be implanted into the fins 66 and/or the nanostructures 55. The n-type impurities may be any of the n-type impurities previously described, and the p-type impurities may be any of the p-type impurities previously described. The LDD regions may have a concentration of impurities in the range of 10¹⁵ cm⁻³ to 10¹⁹ cm⁻³. An anneal process may be used to repair implant damage and to activate the implanted impurities.

In FIGS. 8A and 8B, the first spacer layer 80 and the second spacer layer 82 are etched to form first spacers 81 and second spacers 83. As will be discussed in greater detail below, the first spacers 81 and the second spacers 83 act to self-aligned subsequently formed source/drain regions, as well as to protect sidewalls of the fins 66 and/or nanostructure 55 during subsequent processing. The first spacer layer 80 and the second spacer layer 82 may be etched using a suitable etching process, such as an isotropic etching process (e.g., a wet etch process), an anisotropic etching process (e.g., a dry etching process), or the like. In some embodiments, the material of the second spacer layer 82 has a different etch rate than the material of the first spacer layer 80, such that the first spacer layer 80 may act as an etch stop layer when patterning the second spacer layer 82 and such that the second spacer layer 82 may act as a mask when patterning the first spacer layer 80. For example, the second spacer layer 82 may be etched using an anisotropic etch process wherein the first spacer layer 80 acts as an etch stop layer, wherein remaining portions of the second spacer layer 82 form second spacers 83 as illustrated in FIG. 8A. Thereafter, the second spacers 83 act as a mask while etching exposed portions of the first spacer layer 80, thereby forming first spacers 81 as illustrated in FIG. 8A.

As illustrated in FIG. 8A, the first spacers 81 and the second spacers 83 are disposed on sidewalls of the fins 66 and/or nanostructures 55. As illustrated in FIG. 8B, in some embodiments, the second spacer layer 82 may be removed from over the first spacer layer 80 adjacent the masks 78, the dummy gates 76, and the dummy gate dielectrics 71, and the first spacers 81 are disposed on sidewalls of the masks 78, the dummy gates 76, and the dummy gate dielectrics 71. In other embodiments, a portion of the second spacer layer 82 may remain over the first spacer layer 80 adjacent the masks 78, the dummy gates 76, and the dummy gate dielectrics 71.

It is noted that the above disclosure generally describes a process of forming spacers and LDD regions. Other processes and sequences may be used. For example, fewer or additional spacers may be utilized, a different sequence of steps may be utilized (e.g., the first spacers 81 may be patterned prior to depositing the second spacer layer 82), additional spacers may be formed and removed, and/or the like. Furthermore, the n-type and p-type devices may be formed using different structures and steps, for example by masking the first region 50A to form p-type devices in the second region 50B and by masking the second region 50B to form n-type devices in the first region 50A, or vice versa.

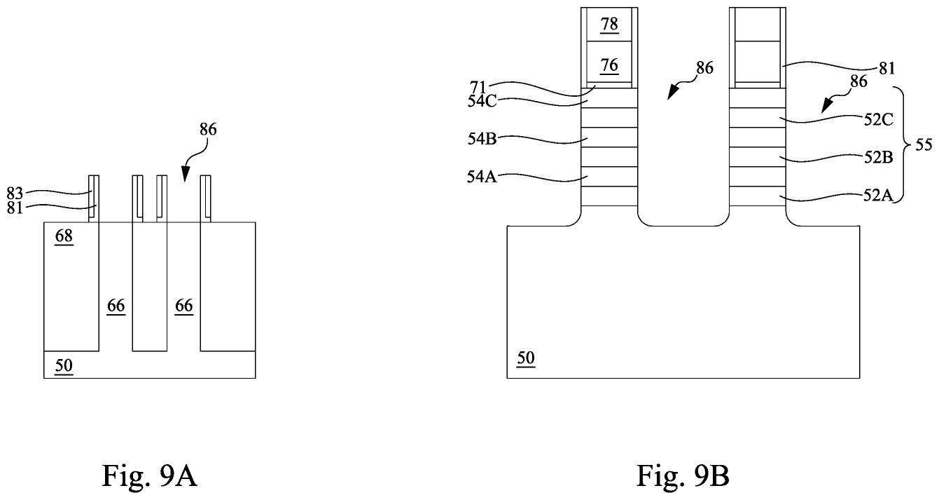

In FIGS. 9A and 9B, first recesses 86 are formed in the fins 66, the nanostructures 55, and the substrate 50, in accordance with some embodiments. Epitaxial source/drain regions will be subsequently formed in the first recesses 86. The first recesses 86 may extend through the first nanostructures 52 and the second nanostructures 54, and into the substrate 50. As illustrated in FIG. 9A, top surfaces of the STI regions 68 may be level with bottom surfaces of the first recesses 86. In various embodiments, the fins 66 may be etched such that bottom surfaces of the first recesses 86 are disposed below the top surfaces of the STI regions 68. The first recesses 86 may be formed by etching the fins 66, the nanostructures 55, and the substrate 50 using anisotropic etching processes, such as RIE, NBE, or the like. The first spacers 81, the second spacers 83, and the masks 78 mask portions of the fins 66, the nanostructures 55, and the substrate 50 during the etching processes used to form the first recesses 86. A single etch process or multiple etch processes may be used to etch each layer of the nanostructures 55 and/or the fins 66. Timed etch processes may be used to stop the etching of the first recesses 86 after the first recesses 86 reach a desired depth.

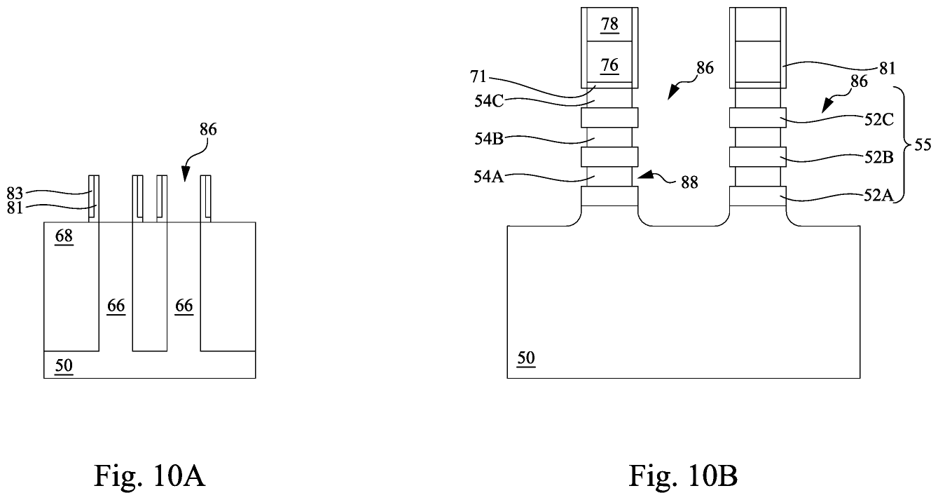

In FIGS. 10A and 10B, portions of sidewalls of the layers of the multi-layer stack 64 formed of the first semiconductor materials (e.g., the first nanostructures 52) exposed by the first recesses 86 are etched to form sidewall recesses 88 in the first region 50A and the second region 50B. Although sidewalls of the first nanostructures 52 in sidewall recesses 88 are illustrated as being straight in FIG. 10B, the sidewalls may be concave or convex. The sidewalls may be etched using isotropic etching processes, such as a wet etch or the like.

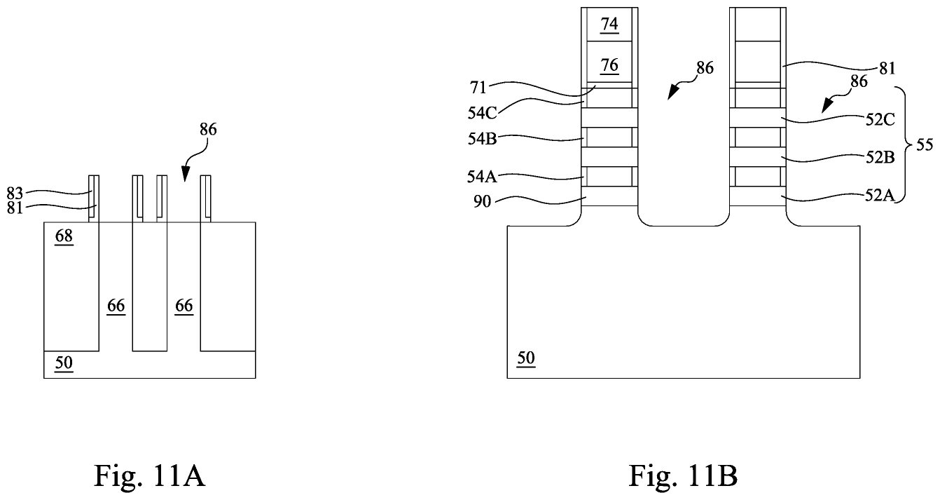

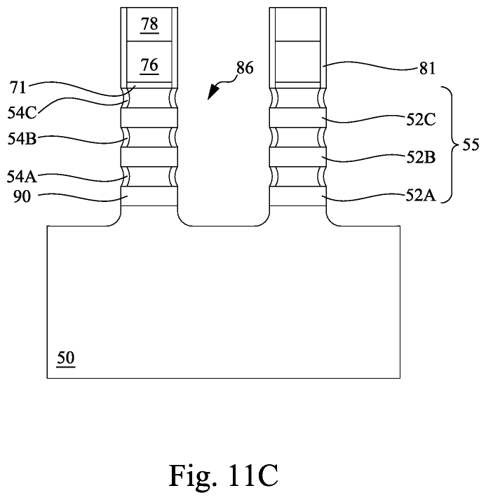

In FIGS. 11A, 11B, and 11C, first inner spacers 90 are formed in the sidewall recess 88. The first inner spacers 90 may be formed by depositing an inner spacer layer over the structures illustrated in FIGS. 10A and 10B. The first inner spacers 90 act as isolation features between subsequently formed source/drain regions and a gate structure. As will be discussed in greater detail below, source/drain regions will be formed in the first recesses 86, while the first nanostructures 52 in the first region 50A and the second region 50B will be replaced with corresponding gate structures.

The inner spacer layer may be deposited by a conformal deposition process, such as CVD, ALD, or the like. The inner spacer layer may comprise a material such as silicon nitride or silicon oxynitride, although any suitable material, such as low-dielectric constant (low-k) materials having a k-value less than about 3.5, may be utilized. The inner spacer layer may then be anisotropically etched to form the first inner spacers 90. Although outer sidewalls of the first inner spacers 90 are illustrated as being flush with sidewalls of the second nanostructures 54 in the first region 50A and the second region 50B, the outer sidewalls of the first inner spacers 90 may extend beyond or be recessed from sidewalls of the second nanostructures 54.

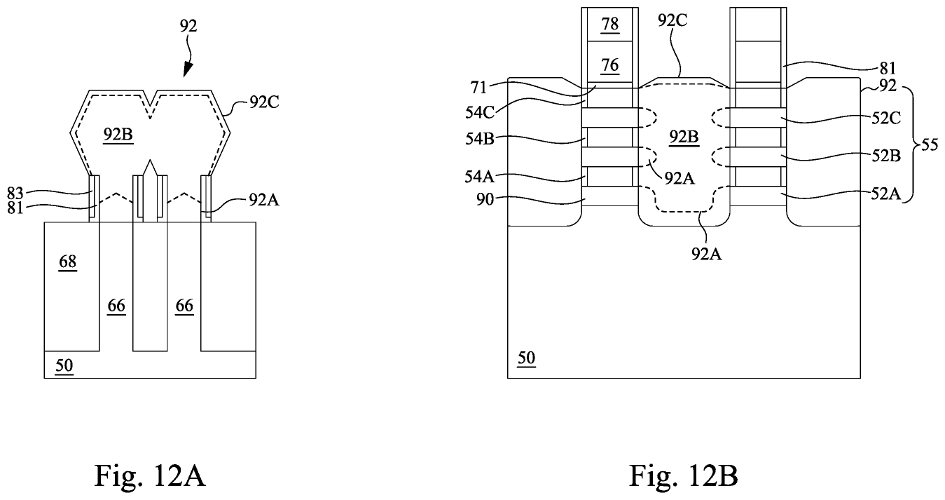

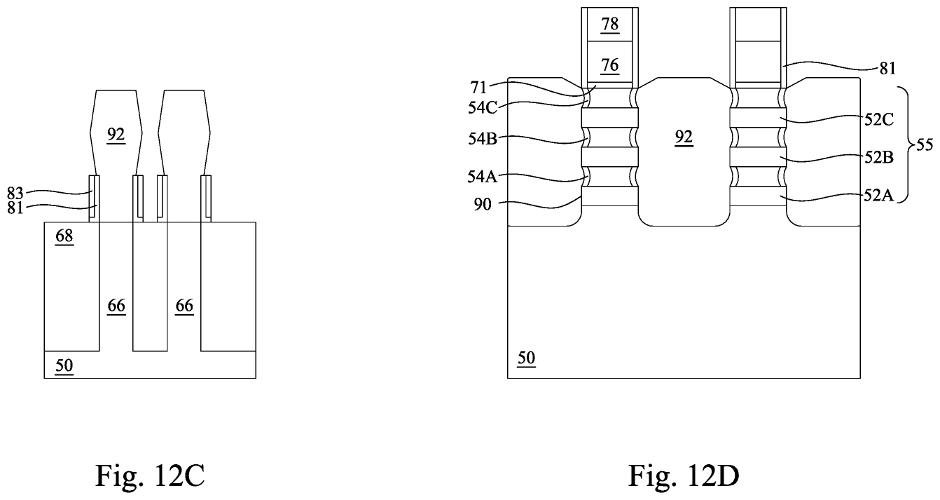

Moreover, although the outer sidewalls of the first inner spacers 90 are illustrated as being straight in FIG. 11B, the outer sidewalls of the first inner spacers 90 may be concave or convex. As an example, FIG. 11C illustrates an embodiment in which sidewalls of the first nanostructures 52 are concave, outer sidewalls of the first inner spacers 90 are concave, and the first inner spacers are recessed from sidewalls of the first nanostructures 52. The inner spacer layer may be etched by an anisotropic etching process, such as RIE, NBE, or the like. The first inner spacers 90 may be used to prevent damage to subsequently formed source/drain regions (such as the epitaxial source/drain regions 92, discussed below with respect to FIGS. 12A, 12B, 12C, and 12D) by subsequent etching processes, such as etching processes used to form gate structures.

In FIGS. 12A, 12B, 12C, and 12D, epitaxial source/drain regions 92 are formed in the first recesses 86. In some embodiments, the epitaxial source/drain regions 92 may exert stress on the second nanostructures 54 in the first region 50A and the second region 50B, thereby improving performance. As illustrated in FIG. 12B, the epitaxial source/drain regions 92 are formed in the first recesses 86 such that each dummy gate 76 is disposed between respective neighboring pairs of the epitaxial source/drain regions 92. In some embodiments, the first spacers 81 are used to separate the epitaxial source/drain regions 92 from the dummy gates 76 and the first inner spacers 90 are used to separate the epitaxial source/drain regions 92 from the nanostructures 55 by an appropriate lateral distance so that the epitaxial source/drain regions 92 do not short out with subsequently formed gates of the resulting nano-FETs.

The epitaxial source/drain regions 92 may include any acceptable material, such as appropriate for an n-type or p-type device, depending on whether a device is in the first region 50A or second region 50B, etc. For example, when n-type devices are formed, the epitaxial source/drain regions 92 may include materials exerting a tensile strain in the channel regions, such as silicon, SiC, SiCP, SiP, or the like. Similarly, when p-type devices are formed, the epitaxial source/drain regions 92 may include materials exerting a compressive strain in the channel regions, such as SiGe, SiGeB, Ge, GeSn, or the like.

The epitaxial source/drain regions 92, the first nanostructures 52, the second nanostructures 54, and/or the substrate 50 may be implanted with dopants to form source/drain regions, similar to the process previously discussed for forming lightly-doped source/drain regions, followed by an anneal process. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 92 may be in situ doped during growth.

As a result of the epitaxy processes used to form the epitaxial source/drain regions 92, upper surfaces of the epitaxial source/drain regions 92 have facets which expand laterally outward beyond sidewalls of the nanostructures 55. In some embodiments, these facets cause adjacent epitaxial source/drain regions 92 of a same device to merge as illustrated by FIG. 12A. In other embodiments, adjacent epitaxial source/drain regions 92 remain separated after the epitaxy process is completed as illustrated by FIG. 12C. In the embodiments illustrated in FIGS. 12A and 12C, the first spacers 81 may be formed to a top surface of the STI regions 68, thereby blocking the epitaxial growth. In some other embodiments, the first spacers 81 may cover portions of the sidewalls of the nanostructures 55 further blocking the epitaxial growth. In some other embodiments, the spacer etch used to form the first spacers 81 may be adjusted to remove the spacer material to allow the epitaxially grown region to extend to the surface of the STI region 68.

The epitaxial source/drain regions 92 may comprise one or more semiconductor material layers. For example, the epitaxial source/drain regions 92 may comprise a first semiconductor material layer 92A, a second semiconductor material layer 92B, and a third semiconductor material layer 92C. Any number of semiconductor material layers may be used for the epitaxial source/drain regions 92. Each of the first semiconductor material layer 92A, the second semiconductor material layer 92B, and the third semiconductor material layer 92C may be formed of different semiconductor materials and may be doped to different dopant concentrations. In some embodiments, the first semiconductor material layer 92A may have a dopant concentration less than the second semiconductor material layer 92B and greater than the third semiconductor material layer 92C. In embodiments in which the epitaxial source/drain regions 92 comprise three semiconductor material layers, the first semiconductor material layer 92A may be deposited, the second semiconductor material layer 92B may be deposited over the first semiconductor material layer 92A, and the third semiconductor material layer 92C may be deposited over the second semiconductor material layer 92B.

FIG. 12D illustrates an embodiment in which sidewalls of the first nanostructures 52 are concave, outer sidewalls of the first inner spacers 90 are concave, and the first inner spacers 90 are recessed from sidewalls of the second nanostructures 54. As illustrated in FIG. 12D, the epitaxial source/drain regions 92 may be formed in contact with the first inner spacers 90 and may extend past sidewalls of the second nanostructures 54.

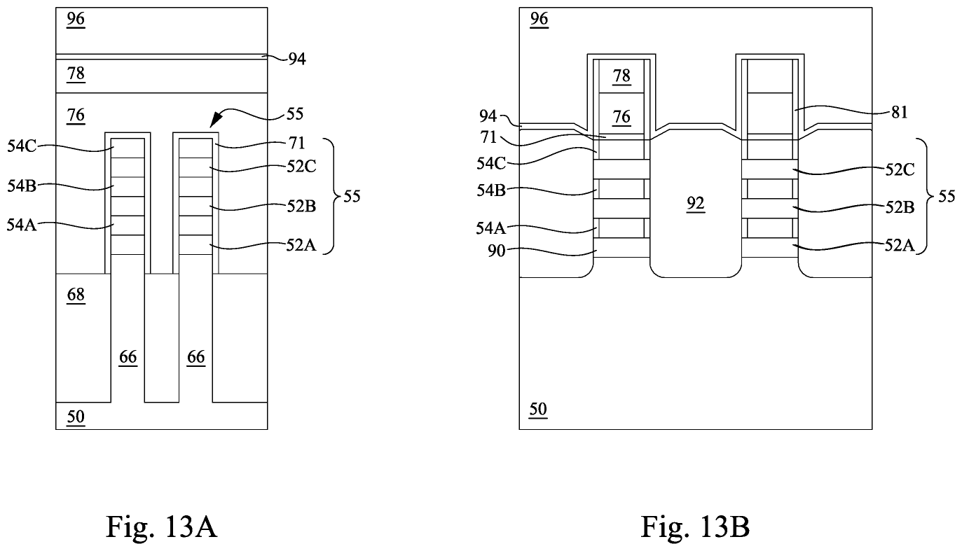

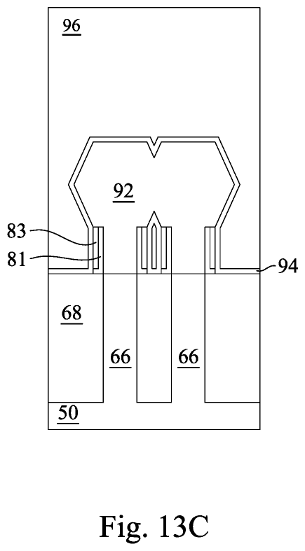

In FIGS. 13A, 13B, and 13C, a first interlayer dielectric (ILD) 96 is deposited over the structure illustrated in FIGS. 6A, 12B, and 12A (the processes of FIGS. 7A-12D do not alter the cross-section illustrated in FIGS. 6A), respectively. The first ILD 96 may be formed of a dielectric material, and may be deposited by any suitable method, such as CVD, plasma-enhanced CVD (PECVD), or FCVD. Dielectric materials may include phospho-silicate glass (PSG), boro-silicate glass (BSG), boron-doped phospho-silicate glass (BPSG), undoped silicate glass (USG), or the like. Other insulation materials formed by any acceptable process may be used. In some embodiments, a contact etch stop layer (CESL) 94 is disposed between the first ILD 96 and the epitaxial source/drain regions 92, the masks 78, and the first spacers 81. The CESL 94 may comprise a dielectric material, such as silicon nitride, silicon oxide, silicon oxynitride, or the like, having a different etch rate than the material of the first ILD 96.

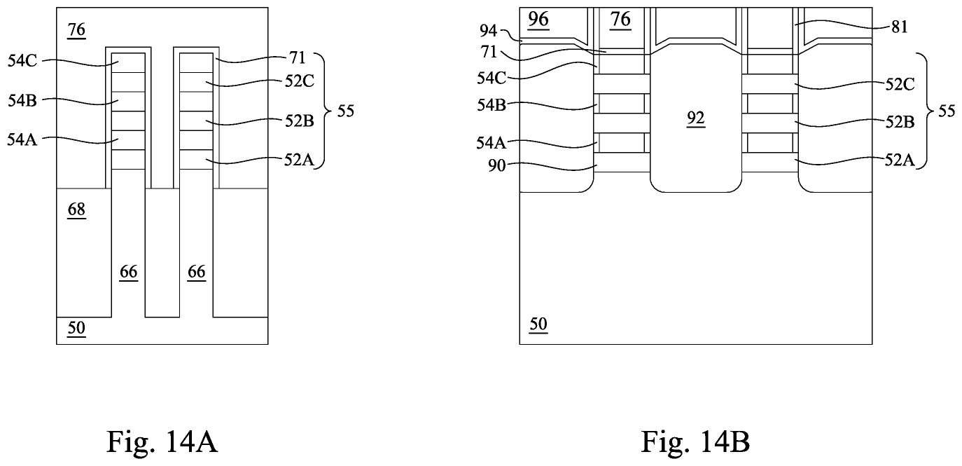

In FIGS. 14A and 14B, a planarization process, such as a CMP, may be performed to level the top surface of the first ILD 96 with the top surfaces of the dummy gates 76 or the masks 78. The planarization process may also remove the masks 78 on the dummy gates 76, and portions of the first spacers 81 along sidewalls of the masks 78. After the planarization process, top surfaces of the dummy gates 76, the first spacers 81, and the first ILD 96 are level within process variations. Accordingly, the top surfaces of the dummy gates 76 are exposed through the first ILD 96. In some embodiments, the masks 78 may remain, in which case the planarization process levels the top surface of the first ILD 96 with the top surface of the masks 78 and the first spacers 81.

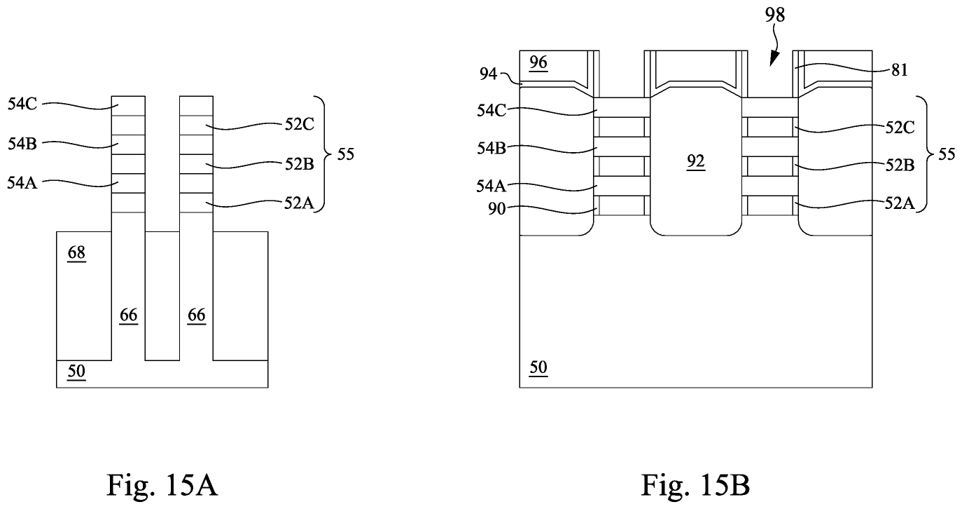

In FIGS. 15A and 15B, the dummy gates 76 and the masks 78 (if present), are removed in one or more etching steps so that second recesses 98 are formed. Portions of the dummy gate dielectrics 71 in the second recesses 98 are also removed. In some embodiments, the dummy gates 76 and the dummy gate dielectrics 71 are removed by an anisotropic dry etch process. For example, the etching process may include a dry etch process using reaction gas(es) that selectively etch the dummy gates 76 at a faster rate than the first ILD 96 or the first spacers 81. Each second recess 98 exposes and/or overlies portions of nanostructures 55, which act as channel regions in subsequently completed nano-FETs. Portions of the nanostructures 55, which act as the channel regions, are disposed between neighboring pairs of the epitaxial source/drain regions 92. During the removal, the dummy gate dielectrics 71 may be used as etch stop layers when the dummy gates 76 are etched. The dummy gate dielectrics 71 may then be removed after the removal of the dummy gates 76.

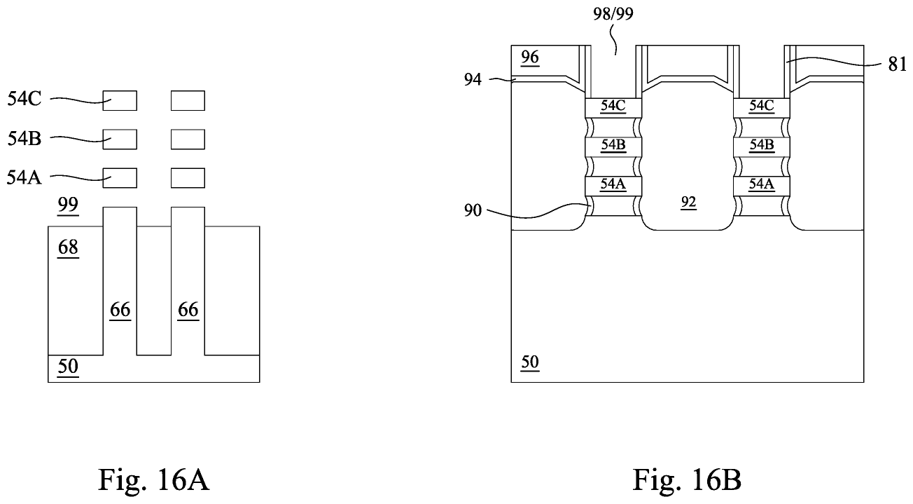

In FIGS. 16A and 16B, the first nanostructures 52 in the first region 50A and the second region 50B are removed, thereby forming openings 99 between the second nanostructures 54 and/or the fins 66. FIG. 16A is an enlarged version of the structure of FIG. 15A after the first nanostructures 52 have been removed, to show better detail for the forming of replacement gates in the following Figures. The first nanostructures 52 may be removed by an isotropic etching process such as wet etch or the like using etchants which are selective to the materials of the first nanostructures 52, while the second nanostructures 54, the substrate 50, the STI regions 68 remain relatively unetched as compared to the first nanostructures 52. In some embodiments in which the first nanostructures 52 include, e.g., SiGe, and the second nanostructures 54 include, e.g., Si or SiC, tetramethylammonium hydroxide (TMAH), ammonium hydroxide (NH₄OH), or the like may be used to remove the first nanostructures 52. In some embodiments in which the first nanostructures 52 include, e.g., Si or SiC, and the second nanostructures 54 include, e.g., SiGe, hydrogen fluoride, another fluorine-based etchant, or the like may be used to remove the first nanostructures 52. The remaining second nanostructures 54 may each be between about 1 nm and 10 nm thick and have a width in FIG. 16A between about 5 nm and 100 nm wide.

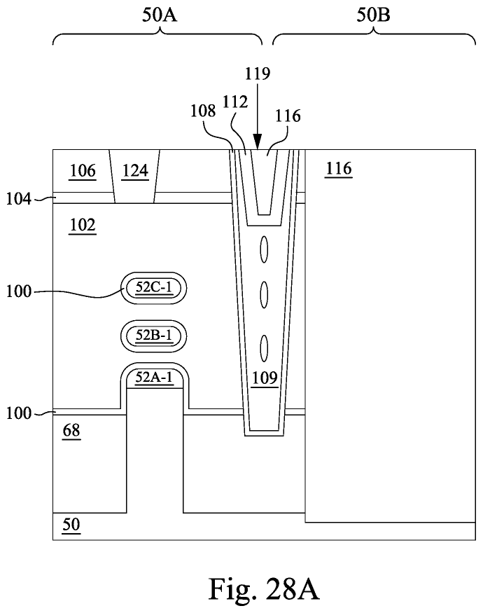

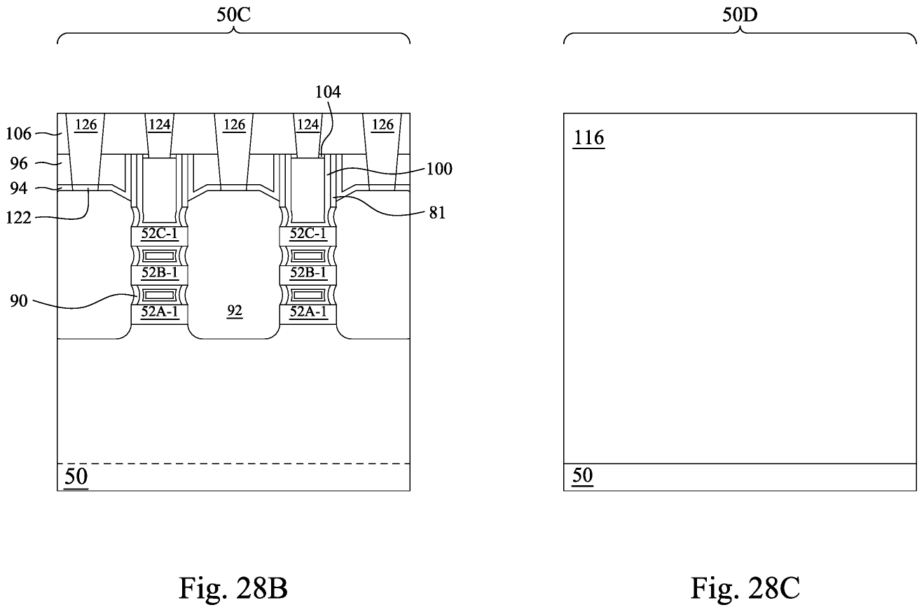

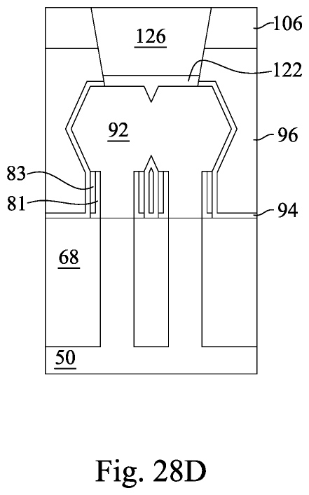

In other embodiments, the first nanostructures 52 in the first region 50A and the second region 50B may comprise different materials and may be removed separately, for example, by forming a mask in the first region 50A and performing an isotropic process such as wet etch or the like using etchants which are selective to the materials of the second nanostructures 54, while the first nanostructures 52, the substrate 50, the STI regions 68 remain relatively unetched as compared to the second nanostructures 54. The first nanostructures 52 in the first region 50A may be removed by forming a mask in the second region 50B and performing an isotropic process such as wet etch or the like using etchants which are selective to the materials of the first nanostructures 52, while the second nanostructures 54, the substrate 50, the STI regions 68 remain relatively unetched as compared to the first nanostructures 52. In other embodiments, the second nanostructures 54 may be removed in the first region 50A and/or the second region 50B and the first nanostructures 52 may remain behind to be utilized as channel regions for corresponding transistors. FIGS. 28A, 28B, and 28C illustrate a structure resulting from such embodiments which illustrate the channel region in the first region 50A and second region 50B as being provided by the first nanostructures 52, for example.

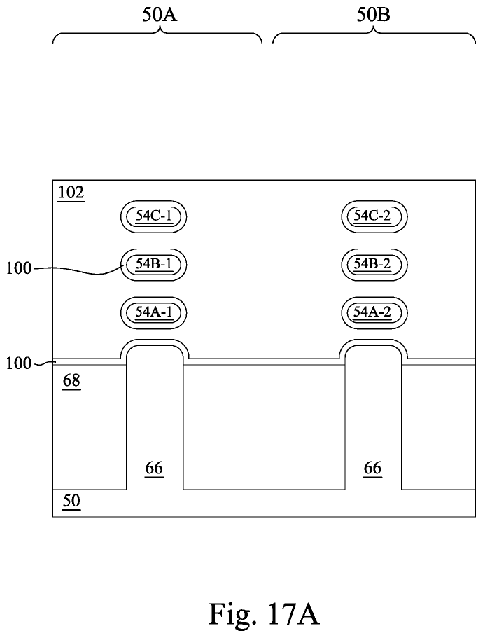

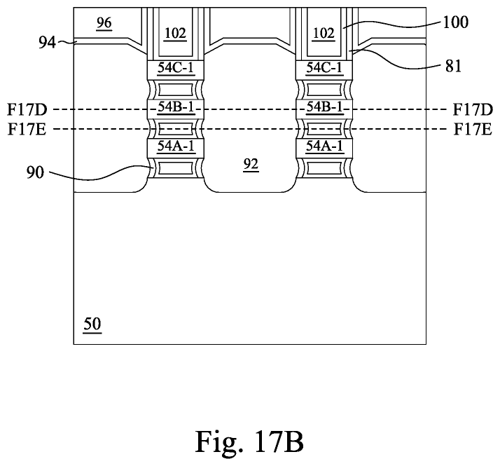

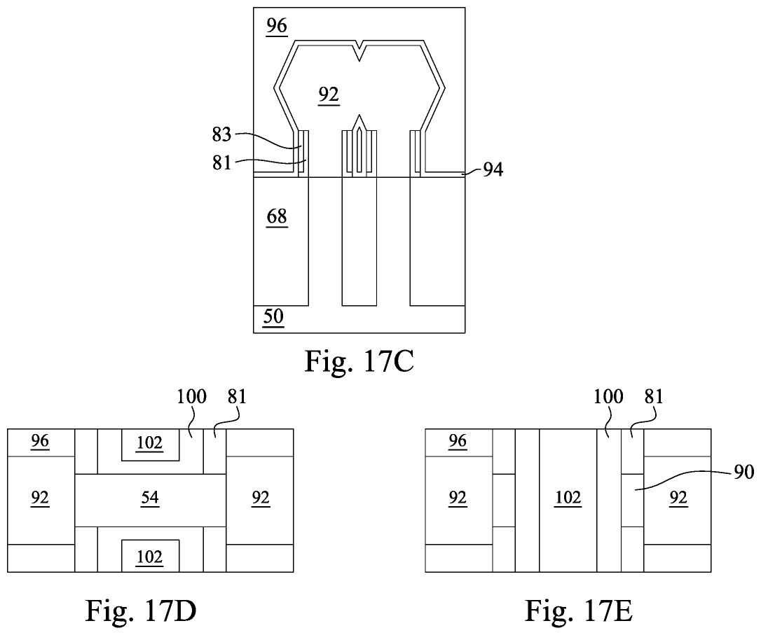

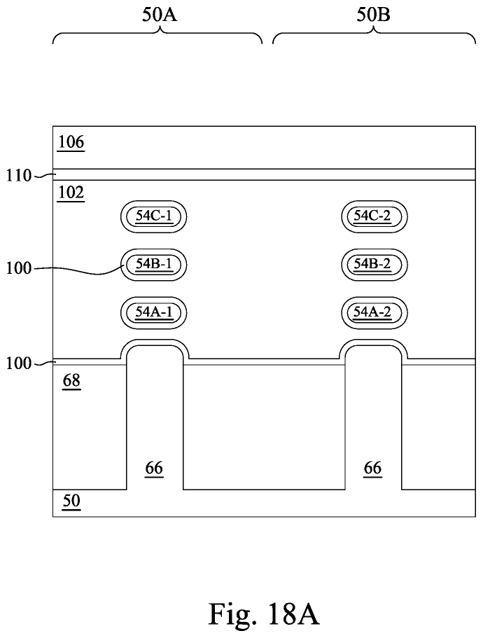

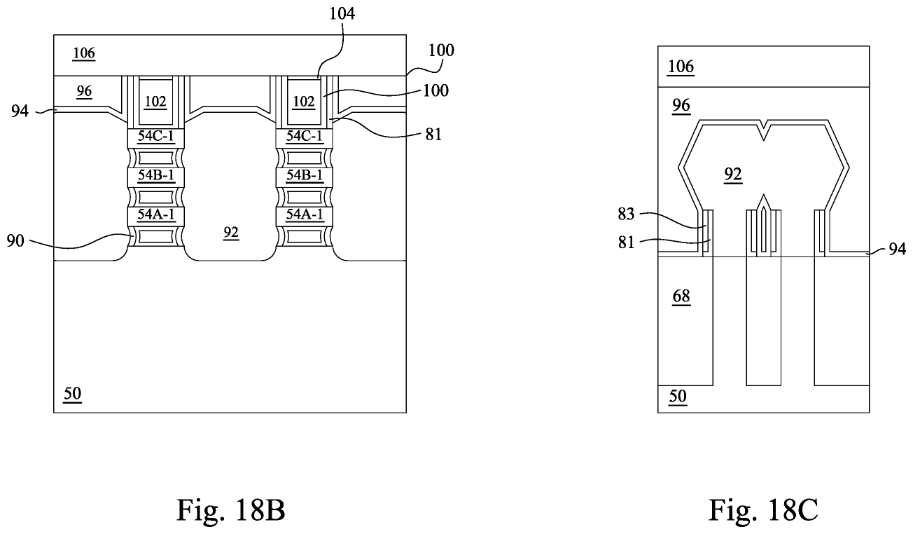

In FIGS. 17A, 17B, 17C, 17D, and 17E, gate dielectric layers 100 and gate electrodes 102 are formed for replacement gates. FIG. 17A has been enlarged to show more detail over FIG. 16A. FIG. 17A also includes labels for the first region 50A and the second region 50B. The view presented in FIG. 18B can apply to both the first region 50A and the second region 50B. The second region 50B will be removed in a subsequent process. The gate dielectric layers 100 are deposited conformally in the second recesses 98 and openings 99. The gate dielectric layers 100 may be formed on top surfaces and sidewalls of the substrate 50 and on top surfaces, sidewalls, and bottom surfaces of the second nanostructures 54. In embodiments where the first nanostructures 52 are used as the channel regions for corresponding transistors, the gate dielectric layers 100 may be formed on top surfaces and sidewalls of the substrate 50 and on top surfaces, sidewalls, and bottom surfaces of the first nanostructures 52. The gate dielectric layers 100 may also be deposited on top surfaces of the first ILD 96, the CESL 94, the first spacers 81, and the STI regions 68.

In accordance with some embodiments, the gate dielectric layers 100 comprise one or more dielectric layers, such as an oxide, a metal oxide, the like, or combinations thereof. For example, in some embodiments, the gate dielectrics may comprise a silicon oxide layer and a metal oxide layer over the silicon oxide layer. In some embodiments, the gate dielectric layers 100 include a high-k dielectric material, and in these embodiments, the gate dielectric layers 100 may have a k value greater than about 7.0, and may include a metal oxide or a silicate of hafnium, aluminum, zirconium, lanthanum, manganese, barium, titanium, lead, and combinations thereof. The structure of the gate dielectric layers 100 may be the same or different in the n-type region 50N and the p-type region 50P. The formation methods of the gate dielectric layers 100 may include molecular-beam deposition (MBD), ALD, PECVD, and the like.

The gate electrodes 102 are deposited over the gate dielectric layers 100, respectively, and fill the remaining portions of the second recesses 98. The gate electrodes 102 may include a metal-containing material such as titanium nitride, titanium oxide, tantalum nitride, tantalum carbide, cobalt, ruthenium, aluminum, tungsten, combinations thereof, or multi-layers thereof. For example, although single layer gate electrodes 102 are illustrated in FIGS. 17A and 17B, the gate electrodes 102 may comprise any number of liner layers, any number of work function tuning layers, and a fill material. Any combination of the layers which make up the gate electrodes 102 may be deposited between adjacent ones of the second nanostructures 54 and between the second nanostructure 54A and the substrate 50.

The formation of the gate dielectric layers 100 in the first region 50A and the second region 50B may occur simultaneously such that the gate dielectric layers 100 in each region are formed from the same materials, and the formation of the gate electrodes 102 may occur simultaneously such that the gate electrodes 102 in each region are formed from the same materials. In some embodiments, the gate dielectric layers 100 in each region may be formed by distinct processes, such that the gate dielectric layers 100 may be different materials and/or have a different number of layers, and/or the gate electrodes 102 in each region may be formed by distinct processes, such that the gate electrodes 102 may be different materials and/or have a different number of layers. Various masking steps may be used to mask and expose appropriate regions when using distinct processes.

After the filling of the second recesses 98 and openings 99, a planarization process, such as a CMP, may be performed to remove the excess portions of the gate dielectric layers 100 and the material of the gate electrodes 102, which excess portions are over the top surface of the first ILD 96. The remaining portions of material of the gate electrodes 102 and the gate dielectric layers 100 thus form replacement gate structures of the resulting nano-FETs. The gate electrodes 102 and the gate dielectric layers 100 may be collectively referred to as “gate structures.”

FIG. 17D is a horizontal cross-sectional view along the reference line F17D-F17D of FIG. 17B, and FIG. 17E is a horizontal cross-sectional view along the reference line F17E-F17E of FIG. 17B. As seen in FIG. 17D, the channel region corresponding to the second nanostructures 54 extends between two adjacent source/drain regions 92. The gate dielectric layers 100 wrap around the second nanostructures 54 and the gate electrodes 102 fill the remainder of the openings 99. As seen in FIG. 17E, the first inner spacers 90 prevent the source drain region 92 from contacting the gate dielectric layers 100.

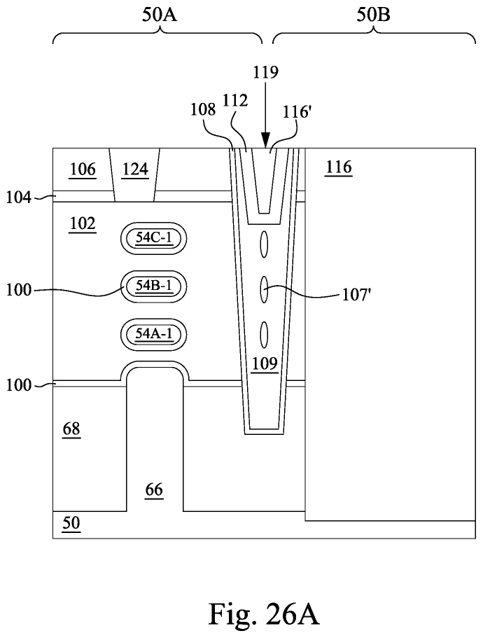

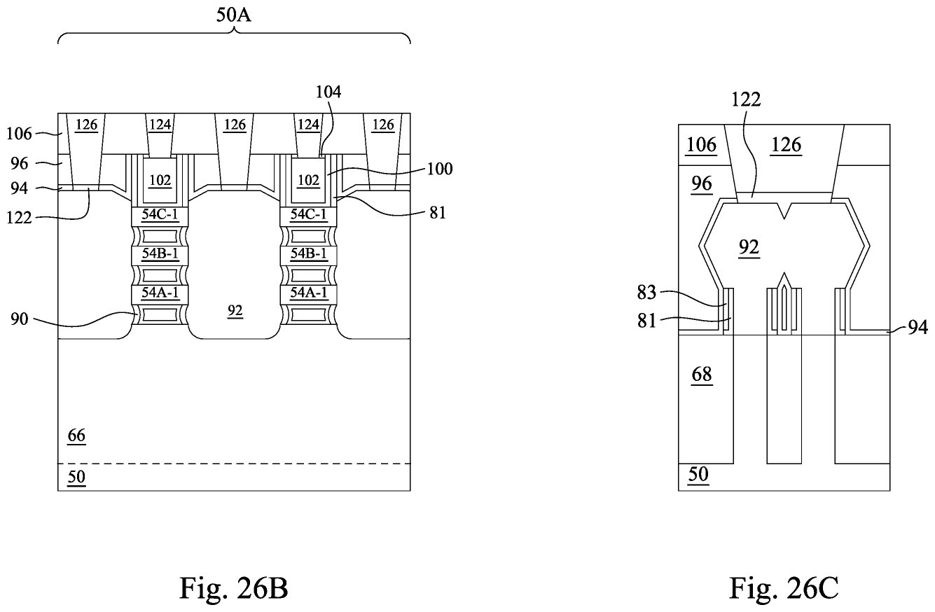

In FIGS. 18A, 18B, and 18C, the gate structure (including the gate dielectric layers 100 and the corresponding overlying gate electrodes 102) is recessed, so that a recess is formed directly over the gate structure and between opposing portions of first spacers 81. A gate mask 104 comprising one or more layers of dielectric material, such as silicon nitride, silicon oxynitride, or the like, is filled in the recess, followed by a planarization process to remove excess portions of the dielectric material extending over the first ILD 96. Subsequently formed gate contacts (such as the gate contacts 124, discussed below with respect to FIGS. 26A, 26B, and 26C) penetrate through the gate mask 104 to contact the top surface of the recessed gate electrodes 102.

As further illustrated by FIGS. 18A, 18B, and 18C, a second ILD 106 is deposited over the first ILD 96 and over the gate mask 104. In some embodiments, the second ILD 106 is a flowable film formed by FCVD. In some embodiments, the second ILD 106 is formed of a dielectric material such as PSG, BSG, BPSG, USG, or the like, and may be deposited by any suitable method, such as CVD, PECVD, or the like.

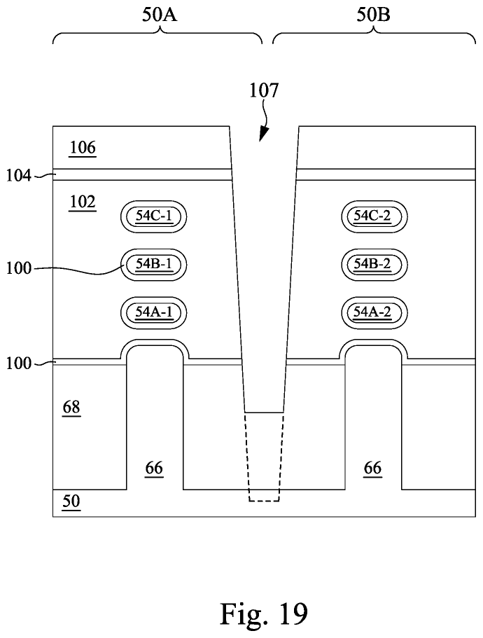

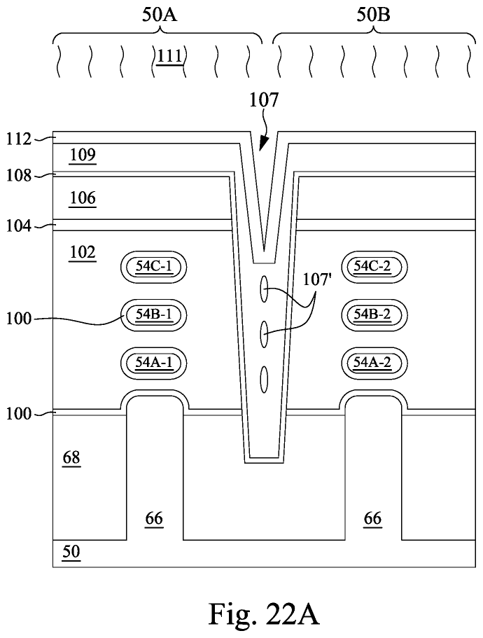

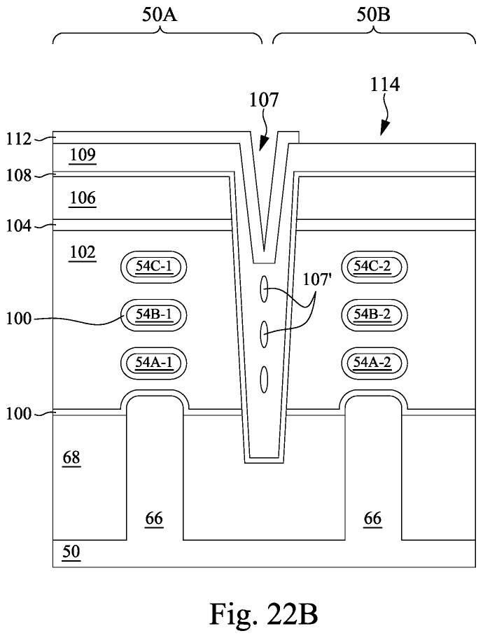

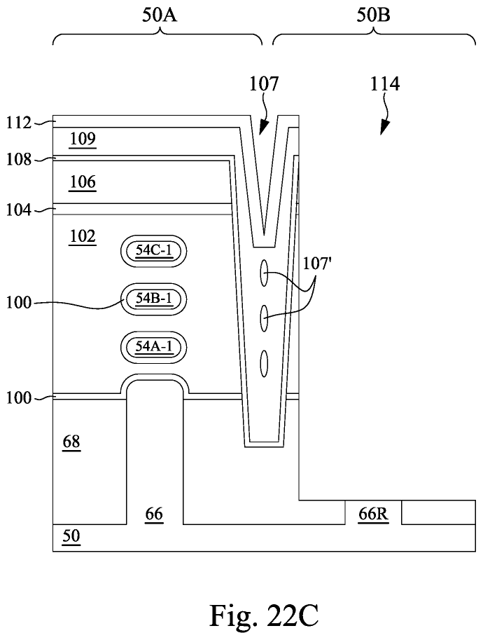

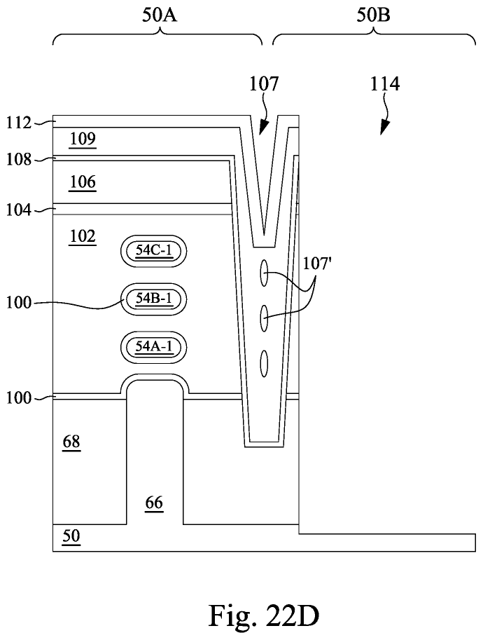

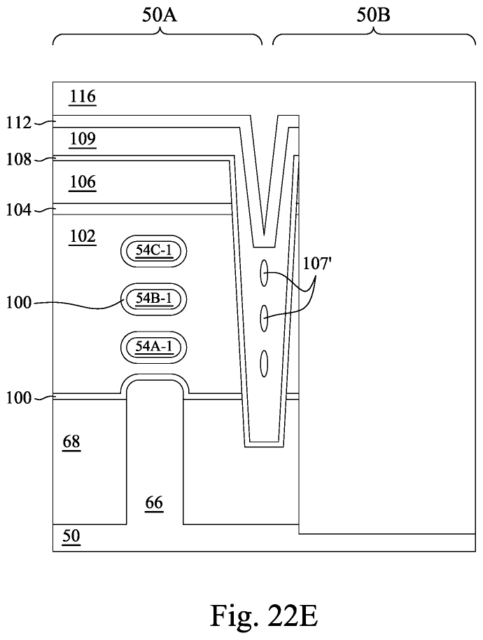

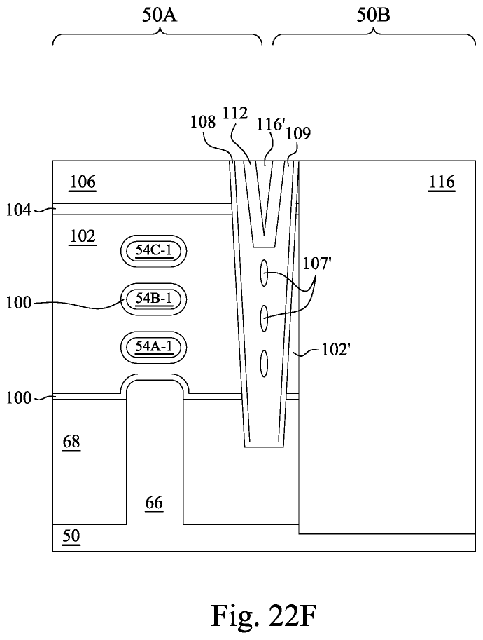

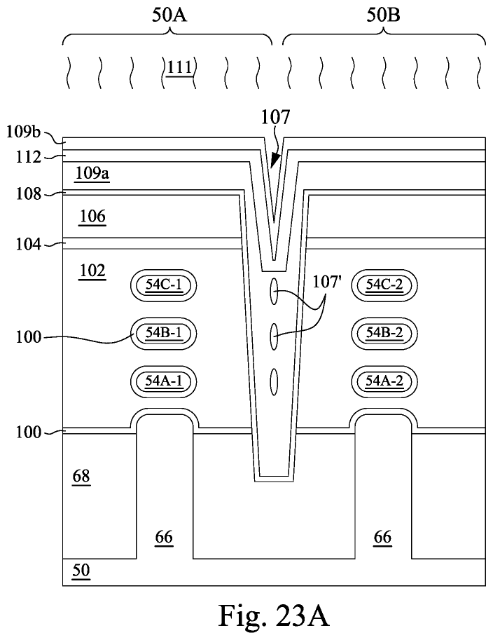

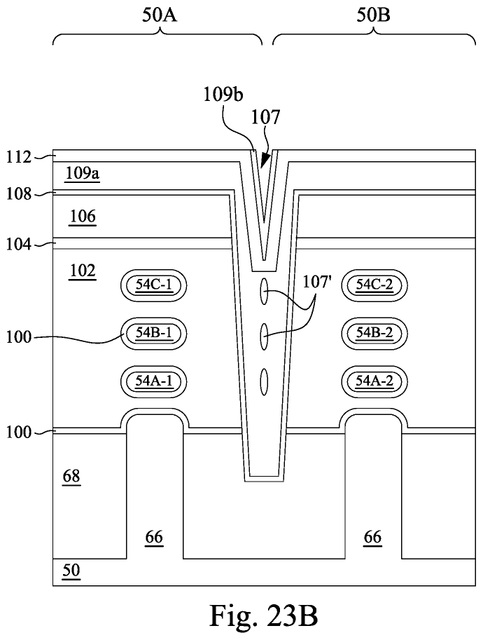

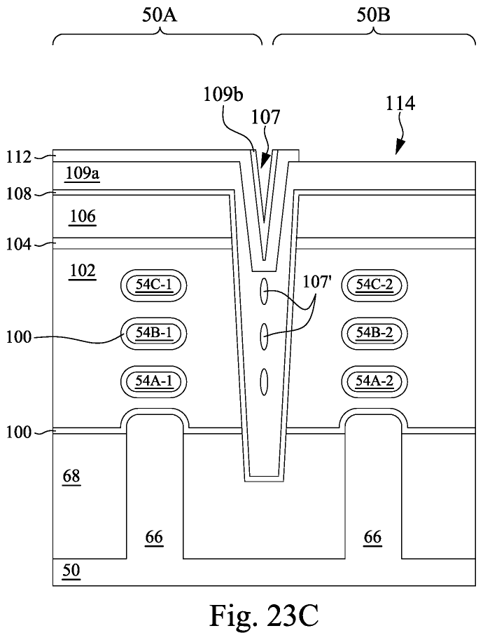

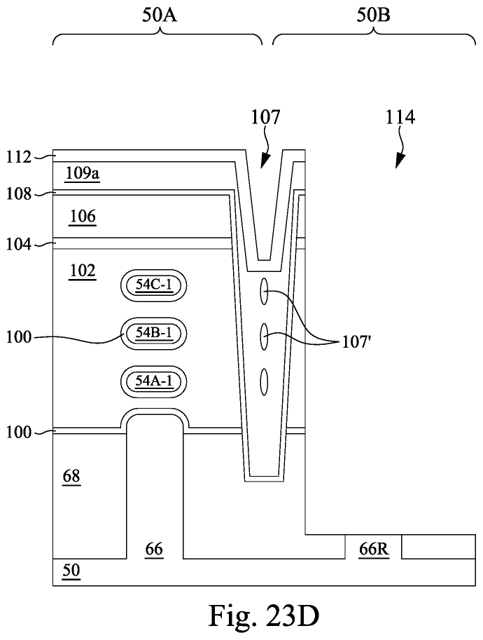

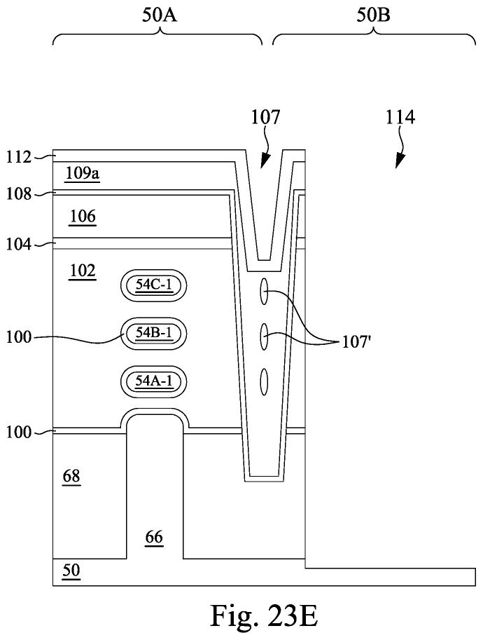

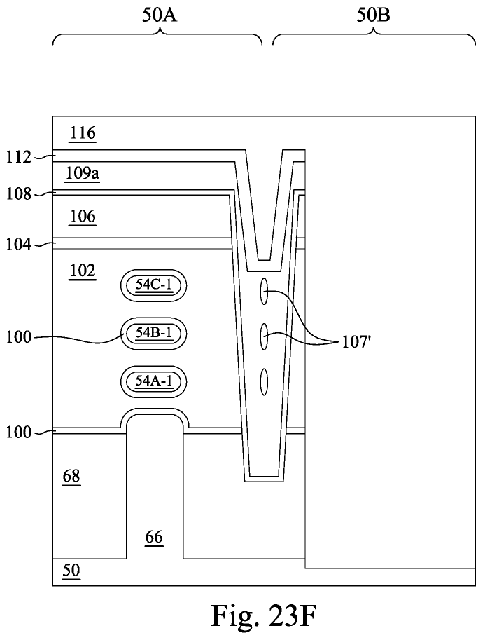

FIGS. 19, 20, 21, 22A, 22B, 22C, 22D, 22E, 22F, 23A, 23B, 23C, 23D, 23E, 23F, 24A, 24B, 24C, 24D, and 24E illustrate intermediate steps in a process of cutting the gate and removing the gate structures in the second region 50B. These Figures are taken along the reference cross-section A-A′ such as illustrated in FIG. 1. In particular, FIGS. 19, 20, and 21 illustrate a process of forming a trench along the gate electrode 102 to separate the gate electrode 102 in the first region 50A from the gate electrode 102 in the second region 50B, followed by a process of depositing an insulating material in the trench. FIGS. 22A through 22F illustrate intermediate steps in a first process of converting a portion of the insulating material into an etch mask, followed by a process of removing the gate structures in the second region 50B. FIGS. 23A through 23F illustrate intermediate steps in a second process of converting a portion of the insulating material into an etch mask, followed by a process of removing the gate structures in the second region 50B. FIGS. 24A through 24E illustrate various views of the completed process as depicted in FIGS. 22A through 22F or FIGS. 23A through 23F. Although these processes are illustrated as being performed prior to the formation of contacts to the source/drain regions 92 and/or gate electrodes 102 (see FIGS. 26A, 26B, and 26C), it should be understood that this process may be performed after the formation of contacts to the source/drain regions 92 and/or gate electrodes 102.

Embodiments provide an edge isolation region at a device edge of a set of transistor devices. To form the edge isolation region, one or more gate structures and fins are removed from the device. For the purposes of the explanation that follows, the edge isolation region will be formed in the second region 50B. Rather than form a separate hard mask for removing the gate structures, embodiments utilize a cut gate dielectric by converting a portion of the cut gate dielectric into a hard mask. These processes are described below.

In FIG. 19, a trench 107 is formed between the first region 50A and the second region 50B. The second nanostructures 54 in the first region 50A have been appended with a “−1” and the second nanostructures 54 in the second region 50B have been appended with a “−2”. The trench 107 may be formed by an acceptable photoetching process. As noted in FIG. 19, the trench 107 may extend through the second ILD 106 through the gate mask 104 through a portion of the gate dielectric layer 100, and into the STI region 68. In some embodiments, the trench 107 may further extend completely through the STI region 68 to expose a portion of the substrate 50. In some embodiments, the trench 107 may continue to extend partially into the substrate 50. Such embodiments are illustrated by the use of the dashed line. As noted in FIG. 19, the trench 107 may have a tapered shape in a cross-sectional view. In other embodiments, the trench 107 may have substantially parallel vertical sidewalls.

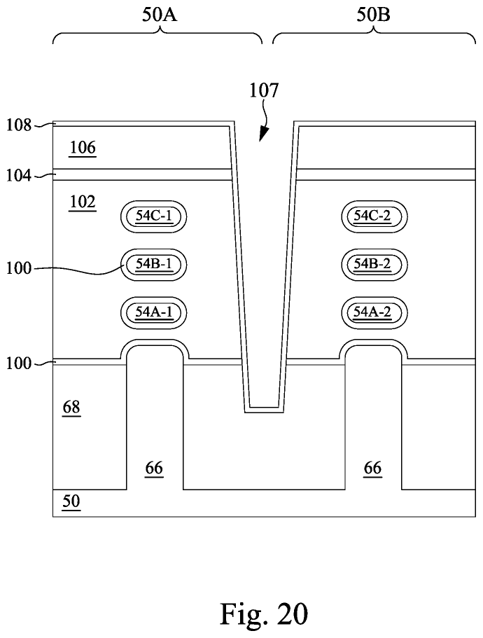

In FIG. 20, a dielectric liner layer 108 is deposited over a top of the second ILD 106. Dielectric liner layer 108 may be deposited by any suitable deposition process such as by ALD, CVD, PE ALD, PE CV to the, the like or combinations thereof. The dielectric liner layer 108 may include silicon nitride, silicon proxy nitride, silicon oxychloride, silicon carbide, the like, or combinations thereof. In some embodiments the dielectric liner layer 108 may be deposited to a thickness between about 4 nm and 8 nm such as between about 5 nm and 6 nm.

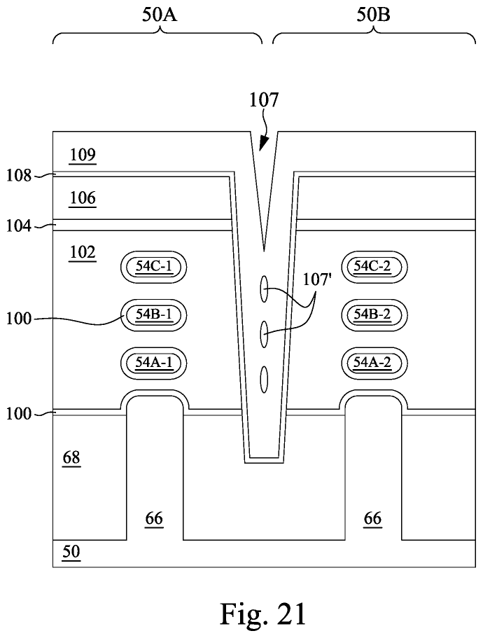

In FIG. 21, a cut gate dielectric 109 is deposited on the dielectric liner layer 108, filling at least part of the trench 107. In some embodiments a portion of the trench may have air gaps 107′ remaining within the trench 107. In some embodiments the trench may be filled to a point where the cut gate dielectric 109 has an upper surface that extends no lower than an upper surface of the gate electrode 102. In some embodiments, the trench 107 may be filled to a point where the cut gate dielectric 109 has an upper surface that extends no lower than the gate mask 104. In some embodiments, the trench 107 may be filled to a point where the cut gate dielectric 109 has an upper surface that extends no lower than an upper surface of the second ILD 106. In some embodiments, the trench 107 may be filled to a point where the cut gate dielectric 109 has an upper surface that extends lower than an upper surface of the gate electrode 102. In some embodiments, the cut gate dielectric 109 is an oxide material, such as silicon oxide, and may be deposited by any suitable process, such as by PECVD, PEALD, TEOS, spincoat, the like, or combinations thereof. The cut gate dielectric 109 may be deposited to have a thickness over the dielectric liner layer 108 between about 16 nm and 25 nm, such as between about 18 nm and 22 nm, and a sidewall thickness in the trench 107 between about 1 nm and 10 nm, such as between about 2 nm and 5 nm. In some embodiments the deposition process may be a conformal process, such that the air gaps 107′ are formed to be within the cut gate dielectric 109 as the two sides of the film of the cut gate dielectric 109 meet each other. In such embodiments, the tapered sidewalls of the trench 107 are filled first at the bottom where the two sides come together, but may have a partial trench 107 remaining after deposition, such as described above and illustrated in FIG. 21.

FIGS. 22A through 22F illustrate a treatment process 111 which converts a portion of the cut gate dielectric 109 into a hard mask 112, in accordance with some embodiments. Following the conversion of the hard mask 112, the hard mask 112 is used to protect a portion of the gate structure which is kept while another portion of the gate structure and the second region 50B is removed by an etching process. In FIG. 22A, the treatment process 111 may be an ammonia treatment. Gaseous ammonia is provided to a processing chamber (not shown) where the gaseous ammonia is soaked onto the upper surfaces of the cut gate dielectric 109. The temperature for the treatment process 111 may be between about 300° C. and about 500° C., the pressure may be between about 2 to 5 torr, the flow rate for the ammonia may be between about 200 to 800 cm, and the flow rate for nitrogen may be between about 10000 and 20000 sccm. An RF power may be provided to enhance the treatment process at about 1000 to 1500 W. Following the treatment process 111, the nitrogen in the ammonia will partially convert the upper surface of the cut gate dielectric 109 into the hard mask 112 by incorporating the nitrogen from the ammonia into the cut gate dielectric 109. The resulting hard mask 112 includes a hybrid composition film which may be considered a nitrogen rich region or nitrogen rich layer. The resulting hybrid film of the hard mask 112 may include silicon oxide, silicon nitride, and/or silicon oxynitride. The thickness of the resulting hard mask 112 may be between about 3 nm and 7 nm such as about 5 nm.

In FIG. 22B, the hard mask 112 is opened by an etching process to create an opening 114 in the hard mask 112. The hard mask 112 may be etched using a suitable etchant in a photo etching process, for example, such as an etchant suitable for etching silicon nitride. The remaining portions of the hard mask 112 cover the portions of the gate structure which are to remain, including those portions of the gate structure in the first region 50A.

In FIG. 22C, the opening 114 is extended through the cut gate dielectric 109, through the dielectric liner layer 108, through the second ILD 106, through the gate mask 104, through the gate electrode 102, through the gate dielectric layer 100, through the second nanostructures 54-1 (54A-1, 54B-1, and 54C-1), into the fin 66, and into the STI region 68. In some embodiments, such as illustrated in FIG. 22C, the opening 114 may only partially remove the fin 66 and/or the exposed portions of the STI region 68, leaving behind a fin remnant 66R. In some embodiments, another portion of the STI region 68 may also remain surrounding a base of the fin remnant 66R. Each of the etching processes used to etch the respective layers to extend the opening 114 may be etched using an etchant suitable for the material to be etched. In some embodiments, the hard mask 112 may be thinned during the etching due to having a same or similar material composition as some of the layers. For example, the dielectric liner layer 108 may be silicon nitride which may have a similar etch rate as the hard mask 112, and so the hard mask 112 may be thinned by a similar thickness as the dielectric liner layer 108 during etching the dielectric liner layer 108. In some embodiments, the hard mask 112 may be removed through the process of extending the opening 114, and other layers used as an etch mask, such as a portion of the cut gate dielectric 109 or a portion of the liner layer 108 (for etching layers below the liner layer 108), etc.

In FIG. 22D, in accordance with some embodiments, the fin remnant 66R is removed as well as the exposed portion of the STI region 68 while continuing to extend the opening 114. Subsequent Figures will be based on FIG. 22D, but it should be understood that the structure in FIG. 22C may instead be used for subsequent processes.

FIG. 22E, the edge isolation region 116 is deposited in the opening 114. The edge isolation region 116 may be deposited using any suitable deposition process such as spin on, flowable CVD, CVD, ALD, PVD, etc., or combinations thereof. In some embodiments, the edge isolation region 116 may be any suitable isolation material such as those described above with respect to the STI region 68. In an embodiment, the material of the edge isolation region 116 may be a polyimide material a polymer, or the like.

In FIG. 22F, a planarization process such as a CMP process, grinding process, etching process, or combinations thereof may be used to remove an upper portion of the edge isolation region 116, and flatten the upper surface of the edge isolation region 116 so that it is level with an upper surface of the second ILD 106. This process may also remove portions of the dielectric liner layer 108, the hard mask 112, and the cut dielectric 109 which extend horizontally above upper surfaces of the second ILD 106. As illustrated in FIG. 22F, this provides an edge isolation region 116 in the second region 50B. A portion 102′ of the gate electrode 102 may remain in the second region 50B in some embodiments, the portion 102′ of the gate electrode 102 not being electrically connected to any of the conductive elements remaining. An edge isolation artifact 116′ of the material of the edge isolation region 116 may also be disposed between adjacent legs of the hard mask 112 or between adjacent legs of the cut gate dielectric 109. Further, the dielectric liner layer 108, cut gate dielectric 109, hard mask 112, and edge isolation artifact 116′ may each have upper surfaces which are level with the upper surface of the second ILD 106 and the edge isolation region 116.

FIGS. 23A through 23F illustrate another treatment process 111 which converts a portion of the cut gate dielectric 109 into a hard mask 112, in accordance with other embodiments. In the embodiments of FIGS. 23A through 23F, the cut gate dielectric 109 is deposited to a thickness between about 20 nm and about 40 nm, such as between about 25 nm and 35 nm, such as about 30 nm. Following the conversion of the portion of the cut gate dielectric 109 into the hard mask 112, the hard mask 112 is used to protect a portion of the gate structure which is kept while another portion of the gate structure the second region 50B is removed by an etching process.

In FIG. 23A, the treatment process 111 may be a nitrogen plasma. Nitrogen gas is provided to a processing chamber (not shown) and ignited into a plasma. The energy used to ignite the plasma may be between about 0.3-1.0 key at a pressure between 1×10⁻⁶ to about 1×10⁻⁷ torr. The nitrogen (N₂) is excited into nitrogen ions in the process and are propelled toward the cut gate dielectric 109, where the nitrogen ions are embedded within the cut gate dielectric 109. The resulting dosing may bet between 1×10¹⁵ to 1×10¹⁶ atoms/cm². Due to the excited state, the nitrogen ions will concentrate at a position below the surface of the cut gate dielectric 109, about 3 nm to about 7 nm below the surface of the cut gate dielectric 109, such as about 5 nm below the surface of the cut gate dielectric 109. Following the implantation of the nitrogen ions, the cut gate dielectric 109 may be annealed using a suitable annealing process, thereby causing the nitrogen ions to react with the materials of the cut gate dielectric 109. This results in the hard mask 112. A portion of the cut gate dielectric 109, the upper portion 109b remains relatively unchanged, as does a lower portion 109a of the cut gate dielectric 109, because the nitrogen ions do not concentrate enough to cause the composition of the portions 109a and 109b to convert to another material. In contrast, the resulting hard mask 112 includes a hybrid composition film which may be considered a nitrogen rich region or nitrogen rich layer. The resulting hybrid film of the hard mask 112 may include silicon oxide, silicon nitride, and/or silicon oxynitride. The thickness of the resulting hard mask 112 may be between about 3 nm and 7 nm such as about 5 nm.

In FIG. 23B, the upper portion 109B of the cut gate dielectric 109 is removed to reveal the hard mask 112. The upper portion 109B may be removed using any suitable process, such as a chemical mechanical polishing process (CMP), etching process, grinding process, etc. In some embodiments, the trench 107 may continue to have a portion of the upper portion 109B lining the trench 107 following the removal of the upper portion 109B to reveal the hard mask 112.

In FIG. 23C, the hard mask 112 is opened by an etching process to create an opening 114 in the hard mask 112. The hard mask 112 may be etched using a suitable etchant in a photo patterning process, for example, such as used for etching silicon nitride. The remaining portions of the hard mask 112 cover the portions of the gate structure which are to remain, including those portions of the gate structure in the first region 50A.

In FIG. 23D, the opening 114 is extended through the lower portion 109a of the cut gate dielectric 109, through the dielectric liner layer 108, through the second ILD 106, through the gate mask 104, through the gate electrode 102, through the gate dielectric layer 100, through the second nanostructures 54-1 (54A-1, 54B-1, and 54C-1), into the fin 66, and into the STI region 68. The etching process may also remove the remaining upper portion 109b of the cut gate dielectric 109 in the trench 107. In some embodiments, such as illustrated in FIG. 23D, the opening 114 may only partially remove the fin 66 and/or the exposed portions of the STI region 68, leaving behind a fin remnant 66R. In some embodiments, another portion of the STI region 68 may also remain surrounding a base of the fin remnant 66R. Each of the etching processes used to etch the respective layers to extend the opening 114 may be etched using an etchant suitable for the material to be etched. In some embodiments, the hard mask 112 may be thinned during the etching due to having a same or similar material composition as some of the layers. For example, the dielectric liner layer 108 may be silicon nitride which may have a similar etch rate as the hard mask 112, and so the hard mask 112 may be thinned by a similar thickness as the dielectric liner layer 108 during etching the dielectric liner layer 108. In some embodiments, the hard mask 112 may be removed through the process of extending the opening 114, and other layers used as an etch mask, such as a portion of the cut gate dielectric 109 or a portion of the liner layer 108 (for etching layers below the liner layer 108), etc.

In FIG. 23E, in accordance with some embodiments, the fin remnant 66R is removed as well as the exposed portion of the STI region 68 while continuing to extend the opening 114. Subsequent Figures will be based on FIG. 23E, but it should be understood that the structure in FIG. 23D may instead be used for subsequent processes.

FIG. 23F, the edge isolation region 116 is deposited in the opening 114. The edge isolation region 116 may be deposited used using any suitable deposition process such as spin on, flowable CVD, CVD, ALD, PVD, etc., or combinations thereof. In some embodiments, the edge isolation region 116 may be any suitable isolation material such as those described above with respect to the STI region 68. In an embodiment, the material of the edge isolation region 116 may be a polyimide material a polymer, or the like.

In FIGS. 24A, 24B, 24C, 24D, and 24E, a planarization process such as a CMP process, grinding process, etching process, or combinations thereof may be used on the structure of FIG. 23F to remove an upper portion of the edge isolation region 116, and flatten the upper surface of the edge isolation region 116 so that it is level with an upper surface of the second ILD 106. This process may also remove portions of the dielectric liner layer 108, the hard mask 112, and the cut gate dielectric 109 which extend horizontally above upper surfaces of the second ILD 106. As illustrated in FIG. 24A, for example, this provides an edge isolation region 116 in the second region 50B. A portion 102′ of the gate electrode 102 may remain in the second region 50B, in some embodiments. In such embodiments, the portion 102′ of the gate electrode 102 may not be electrically connected to any of the conductive elements remaining. An edge isolation artifact 116′ of the material of the edge isolation region 116 may also be disposed between adjacent legs of the hard mask 112 or between adjacent legs of the cut gate dielectric 109. The edge isolation artifact may have a thickness 116t′ between about 20 nm and 30 nm, such as about 25 nm. A thickness 112t of the hard mask 112 below the edge isolation artifact 116′ may be between about 3 nm and 8 nm, such as about 5 nm. (The same ranges are also applicable to the edge isolation artifact 116t and hard mask 112 of FIG. 22F.) Further, the dielectric liner layer 108, cut gate dielectric 109, hard mask 112, and edge isolation artifact 116′ may each have upper surfaces which are level with the upper surface of the second ILD 106 and the edge isolation region 116.

The structures illustrated in FIGS. 24B, 24C, 24D, 24E are applicable for the structure in both FIGS. 24A and 22F as well. FIG. 24C illustrates a cross-section through the second region 50B along the reference cross-section B-B′ of FIG. 1, which follows from processes which leave behind a fin remnant 66R, such as illustrated above with respect to FIGS. 22C and 23D. FIG. 24D illustrates a cross-section through the second region 50B along the reference cross-section B-B′ of FIG. 1, which follows from processes which remove structures in the second region 50B into the substrate 50, such as illustrated above with respect to FIGS. 22D and 23E.

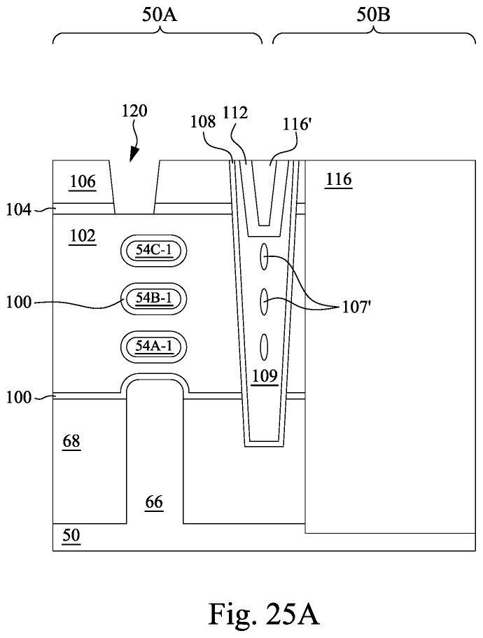

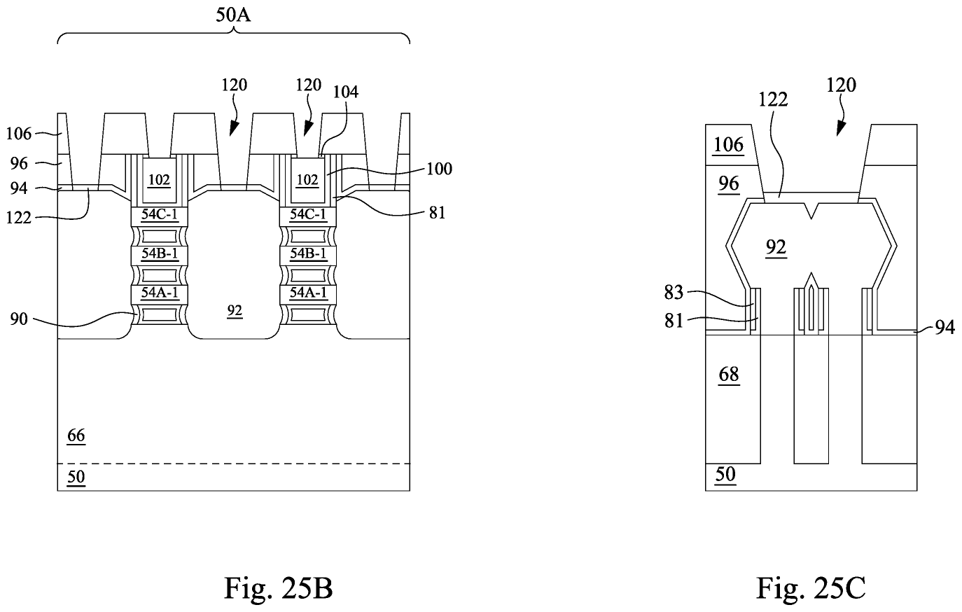

In FIGS. 25A, 25B, and 25C, the second ILD 106, the first ILD 96, the CESL 94, and the gate masks 104 are etched to form third recesses 120 exposing surfaces of the epitaxial source/drain regions 92 and/or the gate structure. The third recesses 120 may be formed by etching using an anisotropic etching process, such as RIE, NBE, or the like. In some embodiments, the third recesses 120 may be etched through the second ILD 106 and the first ILD 96 using a first etching process; may be etched through the gate masks 104 using a second etching process; and may then be etched through the CESL 94 using a third etching process. A mask, such as a photoresist, may be formed and patterned over the second ILD 106 to mask portions of the second ILD 106 from the first etching process and the second etching process. In some embodiments, the etching process may over-etch, and therefore, the third recesses 120 extend into the epitaxial source/drain regions 92 and/or the gate structure, and a bottom of the third recesses 120 may be level with (e.g., at a same level, or having a same distance from the substrate), or lower than (e.g., closer to the substrate) the epitaxial source/drain regions 92 and/or the gate structure. Although FIG. 25B illustrate the third recesses 120 as exposing the epitaxial source/drain regions 92 and the gate structure (e.g., gate electrode 102) in a same cross-section, in various embodiments, the epitaxial source/drain regions 92 and the gate structure may be exposed in different cross-sections, thereby reducing the risk of shorting subsequently formed contacts. After the third recesses 120 are formed, silicide regions 122 are formed over the epitaxial source/drain regions 92. In some embodiments, the silicide regions 122 are formed by first depositing a metal (not shown) capable of reacting with the semiconductor materials of the underlying epitaxial source/drain regions 92 (e.g., silicon, silicon germanium, germanium) to form silicide or germanide regions, such as nickel, cobalt, titanium, tantalum, platinum, tungsten, other noble metals, other refractory metals, rare earth metals or their alloys, over the exposed portions of the epitaxial source/drain regions 92, then performing a thermal anneal process to form the silicide regions 122. The un-reacted portions of the deposited metal are then removed, e.g., by an etching process. Although silicide regions 122 are referred to as silicide regions, silicide regions 122 may also be germanide regions, or silicon germanide regions (e.g., regions comprising silicide and germanide). In an embodiment, the silicide region 122 comprises TiSi, and has a thickness in a range between about 2 nm and about 10 nm.

Next, in FIGS. 26A, 26B, and 26C, contacts 124 and 126 (may also be referred to as contact plugs) are formed in the third recesses 120. The contacts 124 and 126 may each comprise one or more layers, such as barrier layers, diffusion layers, and fill materials. For example, in some embodiments, the contacts 124 and 126 each include a barrier layer and a conductive material, and is electrically coupled to the underlying conductive feature (e.g., gate electrodes 102 and/or silicide region 122 in the illustrated embodiment). The contacts 124 are electrically coupled to the gate electrodes 102 may be referred to as gate contacts, and the contacts 126 are electrically coupled to the silicide regions 122 and may be referred to as source/drain contacts. The barrier layer may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 106.

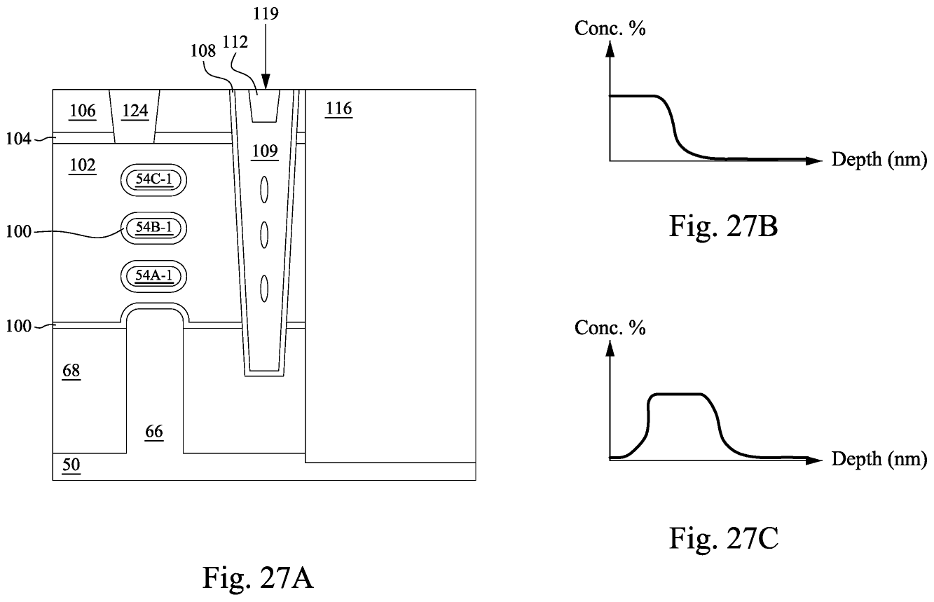

FIG. 27B illustrates a graph of the concentration of nitrogen along a scan line 119, such as illustrated in FIG. 27A. FIG. 27A is a representation of an embodiment similar to that illustrated in FIG. 26A, except that the trench 107 was not made as deep. As a result, the hard mask 112 extends from the top surface in the area of the cut gate dielectric 109. Scan lines 119 are also illustrated in FIGS. 26A and 28A (described below), and a graph of the nitrogen concentration provided in FIG. 27C. As noted in FIG. 27B, the nitrogen concentration at the surface of the hard mask 112 (at the upper surface of the cut gate dielectric 109) may have a large nitrogen concentration content. In some embodiments, the nitrogen concentration may be between about 1E15 cm³ and 1E16 cm³. As the scan line 119 goes deeper, the nitrogen concentration rapidly diminishes to trace (negligible) amounts—such amounts are called zero. In some embodiments, the gradient nitrogen concentration may go from its peak to the trace amounts in about 3 nm to 5 nm. In FIG. 27C, the nitrogen concentration for the hard mask 112 is embedded in the scan line 119 and so a positive gradient, plateau, and negative gradient is observable for nitrogen along the scan line 119. In some embodiments, the positive gradient may demonstrate an increase from trace to peak in about 20 nm to 30 nm, the plateau can last for 3 nm to 8 nm, and the negative gradient may demonstrate a decrease from peak to trace in about 1 nm to 2 nm.

FIGS. 28A, 28B, 28C, and 28D illustrate cross-sectional views of a device according to some alternative embodiments. FIG. 28A illustrates reference cross-section A-A′ illustrated in FIG. 1. FIG. 28B illustrates reference cross-section B-B′ illustrated in FIG. 1. FIG. 28D illustrates reference cross-section D-D′ illustrated in FIG. 1. FIG. 28C illustrates reference cross-section C-C′ illustrated in FIG. 1. In FIGS. 28A-28D, like reference numerals indicate like elements formed by like processes as the structure of FIGS. 26A-26C. However, in FIGS. 28A-28D, channel regions in the first region 50A and the second region 50B are formed utilizing the first nanostructures 52, which may comprise silicon germanium, as channel regions in the first region 50A. The structures of FIGS. 28A-28D may be formed, for example, by removing the second nanostructures in the first region 50A and forming the gate dielectric layer 100 and gate electrode 102 on the first nanostructures 52 in the first region 50A. In some embodiments, devices may be formed with some utilizing the first nanostructures 52 as the channel regions and some using the second nanostructures 54 as the channel regions. Such embodiments may use masking to protect or expose areas so that deposition and etching may occur as described herein.

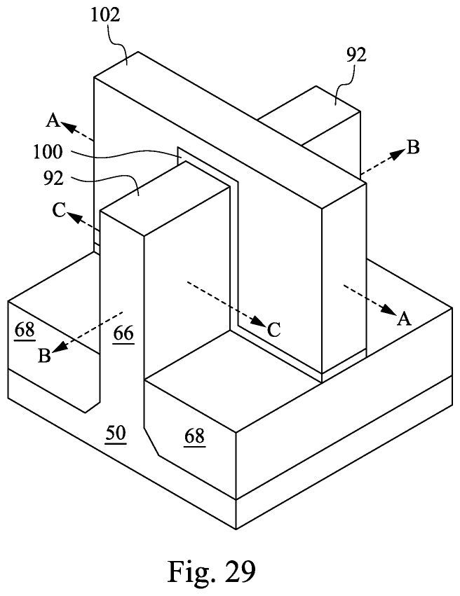

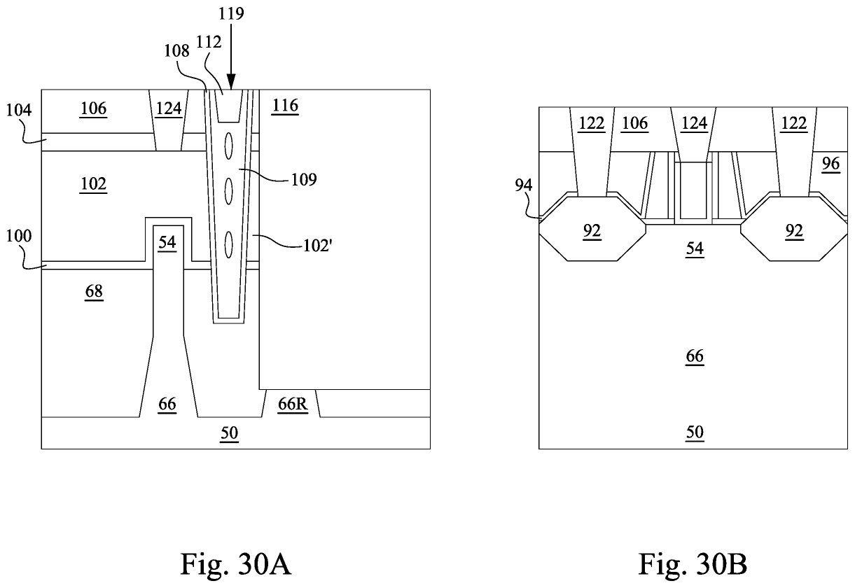

In FIG. 29, a fin field-effect transistor (FinFET) is illustrated in three-dimensional view. Reference lines are provided on the FinFET of FIG. 29 which are referred to with respect to FIGS. 30A and 30B. Like elements are labeled with like references as those discussed above with respect to the nano-FET. The FinFET of FIG. 29 includes a substrate 50 with a fin 66 extending vertically from the substrate. A top portion of the fin 66 has a channel region 54 under a gate electrode 102 and gate dielectric layer 100. Source/drain regions 92 are disposed on each side of the gate electrode 102 in recessed portions of the fin 66 which have been regrown with the source/drain regions 92. Shallow trench isolations regions 68 surround a base portion of the fin 66.

In FIGS. 30A and 30B, FinFET devices are illustrated after undergoing a treatment and edge etch process, such as illustrated above. The treatment may correspond to the treatment process 111 of FIG. 22A or the treatment process 111 of FIG. 24A. After forming a gate electrode 102 over a gate dielectric layer 100, the gate can be cut and a cut gate dielectric 109 deposited in the cut gate. A portion 102′ may remain in some embodiments. A remnant of the fin 66R may also remain in some embodiments, while in other embodiments, the structures down into the substrate 50 may be removed. Scan line 119 is provided which corresponds to the gradients illustrated with respect to FIGS. 27B and/or 27C.

The treatment processes used in the formation of the structures of FIGS. 30A and 30B may convert a portion of the cut gate dielectric 109 into a hard mask which is used to protect a first region which is desired to be kept, while removing an edge portion and replacing it with an edge isolation region 116.

Embodiments advantageously utilize a treatment process to convert a part of a dielectric fill material to a hard mask. Rather than remove a portion of the dielectric fill material and replace it with a series of masks, transforming the dielectric fill material into a hard mask reduces the cost and complexity of forming such devices. Gate materials may be removed and the edge of the final device set. The treatment processes may include an ammonia soak process or a nitrogen plasma treatment process. The ammonia soak process can convert a portion of the dielectric fill material into a hard mask at an upper surface of the dielectric fill material. The plasma treatment process can convert a middle portion of the dielectric fill material into a hard mask after nitrogen ion implantation and activation. The resulting cut area has a gradient of concentration along the cut line for the nitrogen in the converted hard mask.

One embodiment is a method including forming a recess between a first gate region and second gate region of a first transistor, the recess electrically separating the first gate region from the second gate region. The method also includes depositing a dielectric liner in the recess and over an upper surface of the first gate region and the second gate region. The method also includes depositing a dielectric fill material in the recess and over the upper surface of the first gate region and the second gate region. The method also includes treating the dielectric fill material by a first treatment process, the first treatment process altering a portion of the dielectric fill material to form a nitrogen rich layer in the dielectric fill material. The method also includes patterning the nitrogen rich layer to use as an etch mask. The method also includes etching the second gate region to remove the second gate region of the first transistor. In an embodiment, the nitrogen rich layer is formed below an upper surface of the dielectric fill material, and the method may include: planarizing the upper surface of the dielectric fill material to expose the nitrogen rich layer. In an embodiment, the first treatment process includes an ammonia soak. In an embodiment, etching the second gate region forms a second recess adjacent the first gate region, and the method may include: forming an isolation region in the second recess. In an embodiment, depositing the dielectric fill material forms an air gap in the dielectric fill material between the first gate region and the second gate region. In an embodiment, forming the recess may include etching through a metal gate electrode and into a first shallow trench isolation region disposed below the metal gate electrode. In an embodiment, the method may include: after the first treatment process, annealing the dielectric fill material, the nitrogen rich layer being buried beneath an upper surface of the dielectric fill material.

Another embodiment is a method including replacing a dummy gate with a metal gate stack. The method also includes patterning the metal gate stack to form a recess separating the metal gate stack into a first gate stack and a second gate stack. The method also includes depositing a first mask over the first gate stack and the second gate stack, the first mask at least partially filling the recess. The method also includes treating the first mask by a treatment process, the treatment process forming a nitrogen rich region in the first mask. The method also includes patterning their nitrogen rich region to remove a portion of the nitrogen rich region over the second gate stack. The method also includes using the nitrogen rich region as a etch mask, etching away the second gate stack and a corresponding channel region. In an embodiment, the treatment process may include: implanting nitrogen ions into the first mask; and annealing the first mask to activate the nitrogen ions and to form the nitrogen rich region. In an embodiment, the nitrogen rich region is interposed between and upper portion of the first mask and a lower portion of the first mask. In an embodiment, the method may include: planarizing the upper portion of the first mask to expose the nitrogen rich region. In an embodiment, the first mask partially fills the recess, an upper surface of the first mask in the recess being beneath the upper surface of the metal gate stack. In an embodiment, the method may include: depositing an isolation region in place of the second gate stack. In an embodiment, etching away the second gate stack and corresponding channel region further may include removing at least a portion of a shallow trench isolation region below the second gate stack and at least a portion of a semiconductor fin surrounded by the shallow trench isolation region. In an embodiment, the recess extends into a shallow trench isolation region below the metal gate stack.

Another embodiment is a device including a gate region of a transistor disposed on a channel region of the transistor, the channel region disposed over a semiconductor fin. The device also includes a first isolation region disposed under the channel region and surrounding a base portion of the semiconductor fin. The device also includes a second isolation region disposed between the gate region and a third isolation region, the second isolation region having one or more air gaps disposed therein, and upper surface of the second isolation region having a nitrogen rich portion. In an embodiment, the nitrogen rich portion has a negative gradient running vertically from an upper surface of the second isolation region toward a lower surface of the second isolation region. In an embodiment, the third isolation region is disposed over a remnant of a second semiconductor fin. In an embodiment, the second isolation region extends below an upper surface of the first isolation region. In an embodiment, a gate metal is interposed between the second isolation region and the third isolation region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a recess between a first gate region and second gate region of a first transistor, the recess electrically separating the first gate region from the second gate region;
depositing a dielectric liner in the recess and over an upper surface of the first gate region and the second gate region;
depositing a dielectric fill material in the recess and over the upper surface of the first gate region and the second gate region;
treating the dielectric fill material by a first treatment process, the first treatment process altering a portion of the dielectric fill material to form a nitrogen rich layer in the dielectric fill material;
patterning the nitrogen rich layer to use as an etch mask; and
etching the second gate region to remove the second gate region of the first transistor.

2. The method of claim 1, wherein the nitrogen rich layer is formed below an upper surface of the dielectric fill material, further comprising:
planarizing the upper surface of the dielectric fill material to expose the nitrogen rich layer.

3. The method of claim 1, wherein the first treatment process includes an ammonia soak.

4. The method of claim 1, wherein etching the second gate region forms a second recess adjacent the first gate region, further comprising:
forming an isolation region in the second recess.

5. The method of claim 1, wherein depositing the dielectric fill material forms an air gap in the dielectric fill material between the first gate region and the second gate region.

6. The method of claim 1, wherein forming the recess comprises etching through a metal gate electrode and into a first shallow trench isolation region disposed below the metal gate electrode.

7. The method of claim 1, further comprising:
after the first treatment process, annealing the dielectric fill material, the nitrogen rich layer being buried beneath an upper surface of the dielectric fill material.

8. A method comprising:
replacing a dummy gate with a metal gate stack;
patterning the metal gate stack to form a recess separating the metal gate stack into a first gate stack and a second gate stack;
depositing a first mask over the first gate stack and the second gate stack, the first mask at least partially filling the recess;
treating the first mask by a treatment process, the treatment process forming a nitrogen rich region in the first mask;
patterning the nitrogen rich region to remove a portion of the nitrogen rich region over the second gate stack; and
using the nitrogen rich region as a etch mask, etching away the second gate stack and a corresponding channel region.

9. The method of claim 8, wherein the treatment process comprises:
implanting nitrogen ions into the first mask; and
annealing the first mask to activate the nitrogen ions and to form the nitrogen rich region.

10. The method of claim 9, wherein the nitrogen rich region is interposed between and upper portion of the first mask and a lower portion of the first mask.

11. The method of claim 10, further comprising:
planarizing the upper portion of the first mask to expose the nitrogen rich region.

12. The method of claim 8, wherein the first mask partially fills the recess, an upper surface of the first mask in the recess being beneath the upper surface of the metal gate stack.

13. The method of claim 8, further comprising:
depositing an isolation region in place of the second gate stack.

14. The method of claim 8, wherein etching away the second gate stack and corresponding channel region further comprises removing at least a portion of a shallow trench isolation region below the second gate stack and at least a portion of a semiconductor fin surrounded by the shallow trench isolation region.

15. The method of claim 8, wherein the recess extends into a shallow trench isolation region below the metal gate stack.

16. A device comprising:
a gate region of a transistor disposed on a channel region of the transistor, the channel region disposed over a semiconductor fin;
a first isolation region disposed under the channel region and surrounding a base portion of the semiconductor fin; and
a second isolation region disposed between the gate region and a third isolation region, the second isolation region having one or more air gaps disposed therein, and upper surface of the second isolation region having a nitrogen rich portion.

17. The device of claim 16, wherein the nitrogen rich portion has a negative gradient running vertically from an upper surface of the second isolation region toward a lower surface of the second isolation region.

18. The device of claim 16, wherein the third isolation region is disposed over a remnant of a second semiconductor fin.

19. The device of claim 16, wherein the second isolation region extends below an upper surface of the first isolation region.

20. The device of claim 16, wherein a gate metal is interposed between the second isolation region and the third isolation region.
